(19) United States
(12) Patent Application Publication
(10) Pub. No.: US 2026/0081588 A1
(43) Pub. Date: Mar. 19, 2026

(54) CONTROL CIRCUIT, DRIVE CIRCUIT, AND SEMICONDUCTOR CIRCUIT

(71) Applicants: Kabushiki Kaisha Toshiba, Tokyo (JP); Toshiba Electronic Devices & Storage Corporation, Tokyo (JP)

(72) Inventors: Michio SAGAWA, Yokohama Kanagawa (JP); Manami SHIMOKAWA, Kawasaki Kanagawa (JP); Yuichiro NIIKURA, Kamakura Kanagawa (JP)

(21) Appl. No.: 19/209,345

(22) Filed: May 15, 2025

(30) Foreign Application Priority Data
Sep. 18, 2024 (JP) 2024-160706

(51) Int. Cl. H03K 17/0812; H02M 7/5387; H03K 17/18

(52) U.S. Cl. CPC H03K 17/08122; H02M 7/5387; H03K 17/18

(57) ABSTRACT

A control circuit is provided in a drive circuit that is configured to drive a bridge circuit having a plurality of switching devices by controlling the plurality of switching devices respectively using a plurality of control circuits. The control circuit is configured such that a first control signal for controlling a first switching device that is controlled by the control circuit itself among the plurality of switching devices, and a second control signal for controlling a second switching device that is controlled by another control circuit among the plurality of switching devices are input to the control circuit.

### CROSS-REFERENCE TO RELATED APPLICATION

This application is based upon and claims the benefit of priority from Japanese Patent Application No. 2024-160706, filed on Sep. 18, 2024; the entire contents of which are incorporated herein by reference.

### FIELD

Embodiments described herein relate generally to a control circuit, a drive circuit, and a semiconductor circuit.

### BACKGROUND

A drive circuit is known in which a plurality of switching devices are controlled by a plurality of control circuits, respectively. In conventional drive circuits, each of the control circuits cannot determine whether or not it itself is malfunctioning. For this reason, after an external device detects an abnormality such as an overcurrent occurring in a switching device, each of the control circuits starts an operation to protect each of the switching devices that it controls. Therefore, protection of the switching device is delayed, and thus, there is a risk that the switching device may be damaged.

### BRIEF DESCRIPTION OF THE DRAWINGS

FIG. 1 is a circuit diagram showing a semiconductor circuit according to a first embodiment.

FIG. 2 is a circuit diagram showing a control circuit according to the first embodiment.

FIG. 3 is a circuit diagram showing a semiconductor circuit of a second embodiment.

FIG. 4 is a circuit diagram showing a control circuit of the second embodiment.

FIG. 5 is a circuit diagram showing a semiconductor circuit of a third embodiment.

FIG. 6 is a circuit diagram showing a control circuit of a fourth embodiment.

FIG. 7 is a circuit diagram showing a control circuit of a fifth embodiment.

FIG. 8 is a circuit diagram showing a control circuit of a sixth embodiment.

FIG. 9 is a circuit diagram showing a control circuit of a seventh embodiment.

FIG. 10 is a circuit diagram showing a semiconductor circuit of an eighth embodiment.

FIG. 11 is a circuit diagram showing a semiconductor circuit of a ninth embodiment.

FIG. 12 is a circuit diagram showing a semiconductor circuit of a tenth embodiment.

FIG. 13 is a circuit diagram showing a semiconductor circuit of an eleventh embodiment.

FIG. 14 is a circuit diagram showing a semiconductor package of the eleventh embodiment.

FIG. 15 is a circuit diagram showing a semiconductor circuit of a twelfth embodiment.

### DETAILED DESCRIPTION

A control circuit according to embodiments is a control circuit provided in a drive circuit that is configured to drive a bridge circuit having a plurality of switching devices by controlling the plurality of switching devices respectively using a plurality of control circuits. The control circuit is configured such that a first control signal for controlling a first switching device that is controlled by the control circuit itself among the plurality of switching devices, and a second control signal for controlling a second switching device that is controlled by another control circuit among the plurality of switching devices are input to the control circuit.

Hereinafter, a control circuit, a drive circuit, and a semiconductor circuit according to embodiments will be described with reference to the drawings.

### First Embodiment

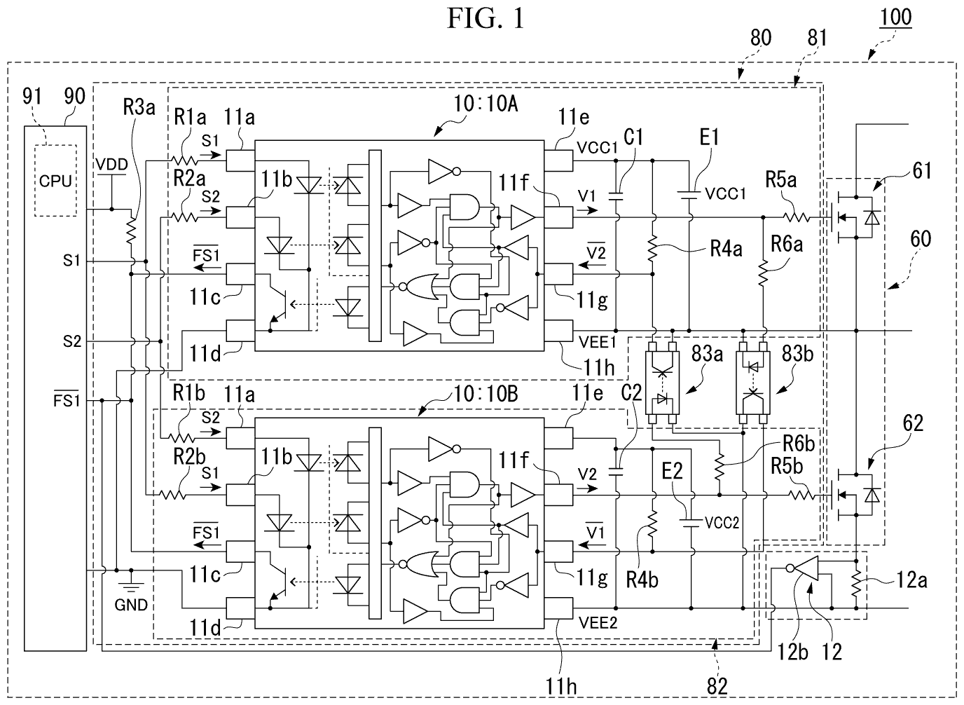

FIG. 1 is a circuit diagram showing a semiconductor circuit 100 according to a first embodiment. The semiconductor circuit 100 shown in FIG. 1 is a circuit that is configured to control an electronic device such as a motor. The semiconductor circuit 100 is a circuit configured by forming power devices such as switching devices 61 and 62 described below, control circuits 10A and 10B which are semiconductor packages described below, isolators 83a and 83b described below, and other circuits on a wire board. The semiconductor circuit 100 is, for example, a part of an inverter device. The semiconductor circuit 100 includes a bridge circuit 60, a drive circuit 80, and a controller 90. The bridge circuit 60 is connected to an electronic device controlled by the semiconductor circuit 100. The bridge circuit 60 is configured to supply power to the electronic device for driving the electronic device. The drive circuit 80 is configured to drive the bridge circuit 60 on the basis of a control signal input from the controller 90.

The bridge circuit 60 includes a plurality of switching devices. In the first embodiment, the bridge circuit 60 includes two switching devices 61 and 62. The switching device 61 and the switching device 62 are connected to each other. In the first embodiment, the two switching devices 61 and 62 are transistors. More specifically, the two switching devices 61 and 62 are N-channel type field effect transistors (FETs). The two switching devices 61 and 62 are metal-oxide-semiconductor field-effect transistors (MOSFETs). The switching device 61 is a high-side switching device. The switching device 62 is a low-side switching device. A source terminal of the switching device 61 is connected to a drain terminal of the switching device 62. The two switching devices 61 and 62 may be any devices as long as they are switching devices. In the present embodiment, the bridge circuit 60 is a half-bridge circuit. The bridge circuit 60 is, for example, an inverter circuit.

The controller 90 is configured to input a control signal for controlling the bridge circuit 60 to the drive circuit 80. In the first embodiment, the controller 90 includes a CPU 91. The CPU 91 is configured to input a control signal to the drive circuit 80.

In the first embodiment, the drive circuit 80 is a gate drive circuit. The drive circuit 80 includes a first drive device 81, a second drive device 82, and isolators 83a and 83b. The first drive device 81 is configured to drive the switching device 61. The second drive device 82 is configured to drive the switching device 62. The first drive device 81 and the second drive device 82 have the same configuration except that they drive different switching devices. Therefore, in the following description, the first drive device 81 will be described as an example of the first drive device 81 and the second drive device 82, and a description of the second drive device 82 may be omitted.

The first drive device 81 has a control circuit 10A. The second drive device 82 has a control circuit 10B. In this way, in the first embodiment, the drive circuit 80 has two control circuits 10A and 10B as a plurality of control circuits. The control circuit 10A is a control circuit that is configured to control one of the two switching devices 61 and 62, that is, the switching device 61. The control circuit 10B is a control circuit that is configured to control the other of the two switching devices 61 and 62, that is, the switching device 62. In other words, the plurality of switching devices 61 and 62 are controlled by the plurality of control circuits 10A and 10B, respectively. In the control circuit 10A, the switching device 61 is a “first switching device” that is controlled by the control circuit 10A itself among the plurality of switching devices, and the switching device 62 is a “second switching device” that is controlled by another control circuit 10B among the plurality of switching devices. In the control circuit 10B, the switching device 62 is a “first switching device” that is controlled by the control circuit 10B itself among the plurality of switching devices, and the switching device 61 is a “second switching device” that is controlled by another control circuit 10A among the plurality of switching devices. In the following description, the control circuit 10A will be described as an example of the control circuits 10A and 10B, and a description of the control circuit 10B may be omitted. In the following description, when there is no particular need to distinguish between the control circuits 10A and 10B, they may be collectively referred to as the control circuit 10.

The control circuit 10 is an integrated circuit (IC). In the first embodiment, the control circuit 10 is an insulated gate drive IC. In the first embodiment, the control circuit 10A and the control circuit 10B are different semiconductor packages. Each of the control circuit 10A and the control circuit 10B is configured by packaging various elements such as a semiconductor chip and an infrared light emitting diode.

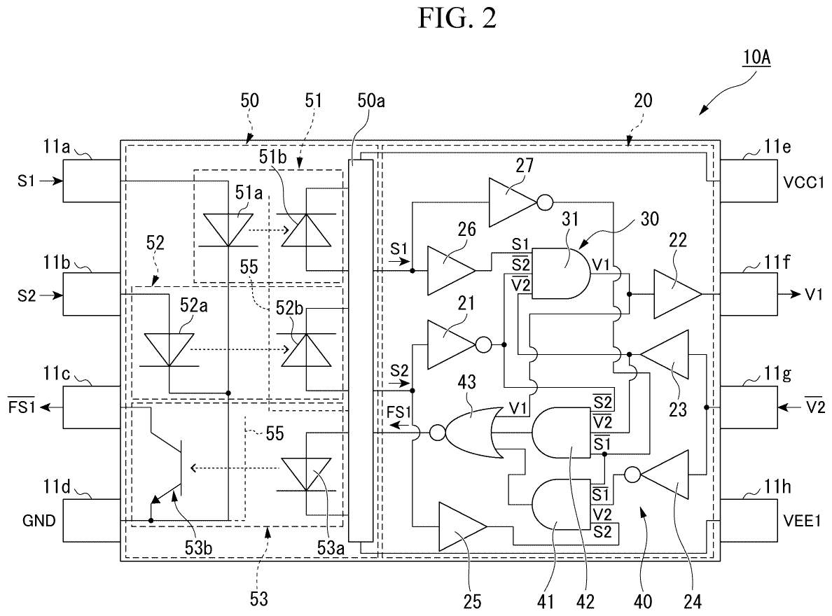

FIG. 2 is a circuit diagram showing the control circuit 10A. As shown in FIG. 2, the control circuit 10A includes a first input terminal 11a, a second input terminal 11b, a fault output terminal 11c, a ground terminal 11d, a positive power supply terminal lie, an output terminal 11f, a third input terminal 11g, a negative power supply terminal 11h, a determination circuit 20, and an insulation transmission device 50.

As shown in FIG. 1, a first control signal S1 is input to the first input terminal 11a from the controller 90. The first control signal S1 is a control signal for controlling the switching device 61. A resistor element R1a is disposed between the first input terminal 11a and the controller 90. The first control signal S1 is input to the first input terminal 11a via the resistor element R1a. The first control signal S1 is, for example, a signal that is at a high level when the switching device 61 is in an ON state and is at a low level when the switching device 61 is in an OFF state.

In the circuits disclosed herein, “a separate element is disposed between a first element and a second element” means that the separate element is provided on a circuit from one of the first element and the second element to the other.

A second control signal S2 is input to the second input terminal 11b from the controller 90. The second control signal S2 is a control signal for controlling the switching device 62. A resistor element R2a is disposed between the second input terminal 11b and the controller 90. The second control signal S2 is input to the second input terminal 11b via the resistor element R2a. The second control signal S2 is, for example, a signal that is at the high level when the switching device 62 is in an ON state and is at the low level when the switching device 62 is in an OFF state.

The fault output terminal 11c is a terminal that outputs a fault signal /FS1. The fault signal /FS1 is input to the controller 90. The fault signal /FS1 is a signal that changes on the basis of a determination result of an abnormality determination operation which will be described below. The fault signal /FS1 is, for example, a negative logic signal that is at the low level when it is determined in the abnormality determination operation that an abnormality has occurred, and is at the high level when it is determined in the abnormality determination operation that no abnormality has occurred. In this specification, a “/” sign described before a symbol indicates that a signal indicated by the symbol is an inverted negative logic signal. In the drawings and tables, negative logic signals are indicated by an upper line instead of the “/” sign. A resistor element R3a is disposed between the fault output terminal 11c and a power supply terminal of terminals of the controller 90 to which a positive power supply voltage VDD is applied.

The ground terminal 11d is connected to the ground GND. A positive power supply voltage VCC1 is applied to the positive power supply terminal 11e by a power supply E1. A negative power supply voltage VEE1 is applied to the negative power supply terminal 11h by the power supply E1. A capacitor C1 is disposed between the positive power supply terminal lie and the negative power supply terminal 11h. The power supply E1 includes a floating power supply.

The output terminal 11f is a terminal that outputs a first output voltage V1. The first output voltage V1 is applied to a gate terminal of the switching device 61. The first output voltage V1 is at the high level when the first control signal S1 is at the high level, and is at the low level when the first control signal S1 is at the low level. A resistor element R5a is disposed between the output terminal 11f and the gate terminal of the switching device 61.

A second output voltage /V2 is input to the third input terminal 11g. The second output voltage /V2 is a voltage output from the isolator 83a on the basis of a second output voltage V2 output from the output terminal 11f of the control circuit 10B. The second output voltage /V2 is a negative logic signal that is at the low level when the second output voltage V2 is at the high level and is at the high level when the second output voltage V2 is at the low level. That is, the second output voltage V2 is inverted via the isolator 83a and is input to the third input terminal 11g as the second output voltage /V2. In the first embodiment, the second output voltage /V2 corresponds to “device information” that indicates a state of the switching device 62. Since the second output voltage V2 output from the output terminal 11f of the control circuit 10B is applied to the gate terminal of the switching device 62, the state of the switching device 62 can be grasped from a value of the second output voltage /V2 on the basis of the second output voltage V2. In the first embodiment, the second output voltage /V2 is information based on a gate voltage (a drive voltage) applied to the switching device 62.

The isolator 83a is an optical coupler having a light emitting diode and a phototransistor. The second output voltage V2 output from the output terminal 11f of the control circuit 10B is input to the isolator 83a. A resistor element R6b is disposed between an input terminal of the isolator 83a and the output terminal 11f of the control circuit 10B. A resistor element R4a is disposed between an output terminal of the isolator 83a and the positive power supply terminal 11e of the control circuit 10A. When the input second output voltage V2 is at the high level, the isolator 83a inputs the second output voltage /V2 which is at the low level to the third input terminal 11g of the control circuit 10A. When the input second output voltage V2 is at the low level, the isolator 83a inputs the second output voltage /V2 which is at the high level to the third input terminal 11g of the control circuit 10A.

As shown in FIG. 2, the insulation transmission device 50 transmits signals in an insulated manner between the first input terminal 11a and the determination circuit 20. The insulation transmission device 50 transmits signals in an insulated manner between the second input terminal 11b and the determination circuit 20. The insulation transmission device 50 transmits signals in an insulated manner between the fault output terminal 11c and the determination circuit 20. The insulation transmission device 50 has a first transmission device 51, a second transmission device 52, a third transmission device 53, a shielding film 55, and a conversion circuit 50a. The shielding film 55 is a member that removes noise in the first transmission device 51, the second transmission device 52, and the third transmission device 53.

The first transmission device 51 transmits the first control signal S1 input to the first input terminal 11a to the determination circuit 20 in an insulated manner. That is, in the first embodiment, the first control signal S1 is transmitted via the insulation transmission device 50 to the determination circuit 20. The first transmission device 51 is an optical coupler having a light emitting diode 51a and a photodiode 51b. When the first control signal S1 is at the high level, a current flows through the light emitting diode 51a, and thus the light emitting diode 51a emits light. When light emitted from the light emitting diode 51a is received by the photodiode 51b, a current flows through the photodiode 51b. The current flowing through the photodiode 51b is converted into a voltage by the conversion circuit 50a and is then output to the determination circuit 20 as the first control signal S1. Thus, the first control signal S1 is transmitted to the determination circuit 20 in an insulated manner via light emitted from the light emitting diode 51a. The conversion circuit 50a is connected to the positive power supply terminal 11e and the negative power supply terminal 11h. The ground (a reference potential) of the determination circuit 20 and the ground (a reference potential) of the conversion circuit 50a are common with respect to each other and are the negative power supply voltage VEE1 applied to the negative power supply terminal 11h.

The second transmission device 52 transmits the second control signal S2 input to the second input terminal 11b to the determination circuit 20 in an insulated manner. That is, in the first embodiment, the second control signal S2 is transmitted via the insulation transmission device 50. The second transmission device 52 is an optical coupler having a light emitting diode 52a and a photodiode 52b. When the second control signal S2 is at the high level, the second transmission device 52, like the first transmission device 51, transmits the second control signal S2 to the determination circuit 20 in an insulated manner via light emitted from the light emitting diode 52a.

The third transmission device 53 transmits a fault signal FS1 input from the fault determination circuit 40 (described below) of the determination circuit 20 to the fault output terminal 11c in an insulated manner. The third transmission device 53 is an optical coupler having a light emitting diode 53a and a phototransistor 53b. When the fault signal FS1 is at the high level, a current flows through the light emitting diode 53a, and thus the light emitting diode 53a emits light. When the light emitted from the light emitting diode 53a is received by the phototransistor 53b, the phototransistor 53b is in an ON state. In this case, the fault output terminal 11c is connected to the ground terminal 11d via the phototransistor 53b, and the fault signal /FS1 output from the fault output terminal 11c is at the low level. On the other hand, when the fault signal FS1 is at the low level, the light emitting diode 53a does not emit light, and the phototransistor 53b is in an OFF state. In this case, the positive power supply voltage VDD is applied to the fault output terminal 11c via the resistor element R3a, and the fault signal /FS1 is at the high level. That is, the fault signal FS1 output from the fault determination circuit 40 is inverted by the third transmission device 53 and is output from the fault output terminal 11c to the controller 90 as the fault signal /FS1. In this embodiment, the light emitting diodes 51a, 52a, and 53a are infrared light emitting diodes. The light emitting diodes 51a, 52a, and 53a may be light emitting diodes that emit any type of light, and may be, for example, blue light emitting diodes or white light emitting diodes. The other light emitting diodes described in this specification may be light emitting diodes that emit any light, may be infrared light emitting diodes, may be blue light emitting diodes, and may be white light emitting diodes.

The determination circuit 20 is a circuit that is configured to perform a determination on the basis of an input signal and outputs a signal on the basis of a determination result. The determination circuit 20 is mounted on a semiconductor chip provided in the control circuit 10. The determination circuit 20 includes an output determination circuit 30 and a fault determination circuit 40.

The output determination circuit 30 is configured to determine whether the level of the first output voltage V1 should be the high level or the low level. The output determination circuit 30 includes an AND circuit 31. Three signals including a first control signal S1 input via a buffer circuit 26, a second control signal /S2 inverted via a NOT circuit 21, and a second output voltage /V2 input via a buffer circuit 23 are input to the AND circuit 31. The AND circuit 31 is configured to output an output signal which is at the high level when all the three input signals are at the high level. The AND circuit 31 is configured to output the output signal which is at the low level when at least one of the three input signals is at the low level. The output signal from the AND circuit 31 is a first output voltage V1, which is output to the output terminal 11f via a buffer circuit 22.

The fault determination circuit 40 is configured to determine whether the level of the fault signal /FS1 should be the high level or the low level. The fault determination circuit 40 includes an AND circuit 41, an AND circuit 42, and a NOR circuit 43. Three signals including the first control signal /S1 inverted via the NOT circuit 27, the second control signal S2 input via a buffer circuit 25, and the second output voltage V2 inverted via a NOT circuit 24 are input to the AND circuit 41. The AND circuit 41 is configured to output an output signal which is at the high level when all the three input signals are at the high level. The AND circuit 41 is configured to output the output signal which is at the low level when at least one of the three input signals is at the low level.

Three signals including the first control signal /S1 inverted through the NOT circuit 27, the second control signal /S2 inverted through the NOT circuit 21, and the second output voltage /V2 input through the buffer circuit 23 are input to the AND circuit 42. The AND circuit 42 is configured to output an output signal which is at the high level when all the three input signals are at the high level. The AND circuit 42 is configured to output the output signal which is at the low level when at least one of the three input signals is at the low level.

Three signals including the first output voltage V1 output from the AND circuit 31, the output from the AND circuit 41, and the output from the AND circuit 42 are input to the NOR circuit 43. The NOR circuit 43 is configured to output a fault signal FS1. The NOR circuit 43 is configured to output the fault signal FS1 which is at the high level when all the three input signals are at the low level. The NOR circuit 43 is configured to output the fault signal FS1 which is at the low level when at least one of the three input signals is at the high level. When the fault signal FS1 is at the high level, the light emitting diode 53a emits light, the phototransistor 53b is in an ON state, and the fault signal /FS1 is at the low level. When the fault signal FS1 is at the low level, the light emitting diode 53a does not emit light, the phototransistor 53b is in an OFF state, and the fault signal /FS1 is at the high level.

The determination circuit 20 is configured to perform an abnormality determination operation for determining whether or not an abnormality has occurred in at least one of a control state of the switching device 61 and a control state of the switching device 62. The abnormality in the control state of the switching device 61 includes an abnormality in the control signal for controlling the switching device 61, that is, an input abnormality, and an abnormality in the ON and OFF state of the switching device 61, that is, an output abnormality. The abnormality in the control state of the switching device 62 includes an abnormality in the control signal for controlling the switching device 62, that is, an input abnormality, and an abnormality in the ON and OFF state of the switching device 62, that is, an output abnormality.

In the first embodiment, the abnormality determination operation includes determining whether or not an abnormality has occurred in at least one of the control states of the two switching devices 61 and 62 on the basis of the first control signal S1, the second control signal S2, and the second output voltage /V2. Table 1 shows the first control signal S1, the second control signal S2, the second output voltage /V2, the first output voltage V1, the fault signal /FS1, and the determination result of the abnormality determination operation.

TABLE 1

| | Level of | Level of | Level of | Level of | | |
|---|---|---|---|---|---|---|
| | first | second | second | first | Level of | |
| | control | control | output | output | fault | |
| | signal | signal | voltage | voltage | signal | Determination |
| No. | S1 | S2 | V̅2̅ | V1 | F̅S̅1̅ | result |
| [1] | High | Low | High | High | High | Pass |
| | | | (Normality) | (Normality) | | |
| [2] | High | High | Low | High | Low | Fail |
| | | (Input | (Output | →Low | | |
| | | abnormality) | normality) | (Protection) | | |
| [3] | High | Low | Low | High | Low | Fail |
| | | | (Output | →Low | | |
| | | | abnormality) | (Protection) | | |
| [4] | High | High | High | High | Low | Fail |
| | | (Input | (Not | →Low | | |
| | | abnormality) | operating) | | | |
| [5] | Low | High | Low | Low | High | Pass |
| | | | (Normality) | (Normality) | | |
| [6] | Low | High | High | Low | Low | Fail |
| | | | (Not | (Normality) | | |
| | | | operating) | | | |
| [7] | Low | Low | High | Low | High | Pass |
| | | | (Normality) | (Normality) | | |
| [8] | Low | Low | Low | Low | Low | Fail |
| | | | (Output | (Normality) | | |
| | | | abnormality) | | | |

In Table 1, a state in which the determination result is “Pass” is a state in which it is determined to be normal, and a state in which the determination result is “Fail” is a state in which it is determined to be abnormal. When the first control signal S1 is at the high level, in a normal state, the second control signal S2 is at the low level, and the first output voltage V1 is at the high level on the basis of the first control signal S1, and the second output voltage V2 is at the low level on the basis of the second control signal S2. Therefore, the second output voltage /V2 that is inverted and input to the control circuit 10A is at the high level. In other words, a state [1] in Table 1 is the normal state.

When the second control signal S2 is at the high level, in a normal state, the first control signal S1 is at the low level, the first output voltage V1 is at the low level on the basis of the first control signal S1, and the second output voltage V2 is at the high level on the basis of the second control signal S2. Therefore, the second output voltage /V2 that is inverted and input to the control circuit 10A is at the low level. In other words, a state [5] in Table 1 is the normal state.

When both the first control signal S1 and the second control signal S2 are at the low level, in the normal state, both the first output voltage V1 and the second output voltage V2 are also at the low level, and the second output voltage /V2 that is inverted and input to the control circuit 10A is at the high level. In other words, [7] in Table 1 is in the normal state.

In the normal state in which the determination result is “Pass” as in [1], [5], and [7] in Table 1, the fault signal /FS1 is at the high level. On the other hand, states in which the determination result is “Fail,” such as [2], [3], [4], [6], and [8] in Table 1, are all the abnormal states. In the abnormal states of [2], [3], [4], [6], and [8], the fault signal /FS1 is at the low level. When it is determined in the abnormality determination operation that an abnormality has occurred in the control state of the switching device 61, the determination result is “Fail”. When it is determined in the abnormality determination operation that an abnormality has occurred in the control state of the switching device 62, the determination result is “Fail”. When it is determined in the abnormality determination operation that an abnormality has occurred in both the control state of the switching device 61 and the control state of the switching device 62, the determination result is “Fail”.

In the first embodiment, the determination circuit 20 is configured to determine whether or not an abnormality occurs in at least one of the control state of the switching device 61 and the control state of the switching device 62 using the output determination circuit 30 and the fault determination circuit 40 described above. For example, in the case of [1] shown in Table 1, the first control signal S1 is at the high level, the second control signal S2 is at the low level, and the second output voltage /V2 is at the high level. In this case, all the three signals S1, /S2, and /V2 input to the AND circuit 31 of the output determination circuit 30 are at the high level. Thus, the AND circuit 31 outputs the first output voltage V1 which is at the high level. It is a normal operation for the first output voltage V1 to be at the high level when the first control signal S1 is at the high level.

Further, in the case of [1], all of the three signals /S1, S2, and V2 input to the AND circuit 41 in the fault determination circuit 40 are at the low level. Thus, the output of the AND circuit 41 is at the low level. In the case of [1], the first control signal /S1 of the three signals /S1, /S2, /V2 input to the AND circuit 42 in the fault determination circuit 40 is at the low level. Therefore, the output of the AND circuit 42 is also at the low level. Low level signals are input to the NOR circuit 43 from the two AND circuits 41 and 42, but the first output voltage V1 input from the AND circuit 31 of the output determination circuit 30 is at the high level. Therefore, the fault signal FS1 output from the NOR circuit 43 is at the low level. Therefore, the fault signal /FS1 output from the fault output terminal 11c is at the high level. That is, the state of the fault signal /FS1 is a state indicating that no abnormality has been detected.

As described above, in the case of [1] in Table 1, the determination circuit 20 determines through the abnormality determination operation that the control state of the two switching devices 61 and 62 are normal. Thus, the control circuit 10A outputs the first output voltage V1 that is at the high level on the basis of the first control signal S1 that is at the high level, and also outputs the fault signal /FS1 which is at the high level that indicates a normal state.

For example, in the case of [2] shown in Table 1, the first control signal S1 is at the high level, the second control signal S2 is at the high level, and the second output voltage /V2 is at the low level. In a switching operation of the two switching devices 61 and 62, since the two switching devices 61 and 62 are never both in the ON state, in the normal state, the first control signal S1 and the second control signal S2 are never both at the high level. Therefore, in the case of [2], an abnormality occurs in at least one of the control signals that controls the two switching devices 61 and 62. In this case, two signals /S2 and /V2 of the three signals S1, /S2 and /V2 input to the AND circuit 31 of the output determination circuit 30 are at the low level. Therefore, the AND circuit 31 outputs the first output voltage V1 which is at the low level. In the normal state, when the first control signal S1 is at the high level, the AND circuit 31 outputs the first output voltage V1 which is at the high level. However, in the case of [2], since an abnormality occurs, the output determination circuit 30 determines that an abnormality occurs in at least one of the control state of the switching device 61 and the control state of the switching device 62, and outputs the first output voltage V1 which is at the low level. In other words, the output determination circuit 30 determines that the two switching devices 61 and 62 are in a short-circuited state, and outputs the first output voltage V1 which is at the low level. Thus, even when the switching device 62 is in the ON state due to the second output voltage V2 which is at the high level, the first output voltage V1 can be at the low level so that the switching device 61 is in the OFF state. Therefore, it is possible to avoid both the two switching devices 61 and 62 being in the ON state and causing a short circuit, thereby protecting the bridge circuit 60. In this way, when it is determined in the abnormality determination operation that the two switching devices 61 and 62 will be in the ON state concurrently, the control circuit 10A sets the switching device 61 to the OFF state.

In the case of [2], the first control signal /S1 of the three signals /S1, S2, and V2 input to the AND circuit 41 in the fault determination circuit 40 is at the low level. Therefore, the output of the AND circuit 41 is at the low level. In the case of [2], all the three signals /S1, /S2, and /V2 input to the AND circuit 42 in the fault determination circuit 40 are at the low level. Therefore, the output of the AND circuit 42 is also at the low level. Furthermore, the first output voltage V1 input from the AND circuit 31 of the output determination circuit 30 to the NOR circuit 43 is also at the low level. Therefore, the fault signal FS1 output from the NOR circuit 43 is at the high level. Thus, the fault signal /FS1 output from the fault output terminal 11c is at the low level. In other words, the state of the fault signal /FS1 is a state indicating that an abnormality has been detected.

As described above, in the case of [2] in Table 1, the determination circuit 20 determines through the abnormality determination operation that at least one of the control state of the switching device 61 and the control state of the switching device 62 is abnormal. Thus, even when the control circuit 10A receives the first control signal S1 which is at the high level, it protects the bridge circuit 60 by the first output voltage V1 being at the low level, and outputs the fault signal /FS1 which is at the low level indicating the abnormal state.

In the case of [2], the second control signal S2 is at the high level, whereas the second output voltage /V2 is at the low level, that is, the second output voltage V2 is at the high level. When the second control signal S2 is at the high level, it is normal for the second output voltage V2 to be at the high level. Therefore, in the case of [2], although an abnormality occurs in the input of the control signal, the output of the second output voltage V2 in response to the second control signal S2 is normal.

For example, in the case of [6] shown in Table 1, the first control signal S1 is at the low level, the second control signal S2 is at the high level, and the second output voltage /V2 is at the high level. In this case, in the normal state, since the second output voltage V2 is at the high level on the basis of the second control signal S2, the second output voltage /V2 is at the low level. However, since the second output voltage /V2 is at the high level, in the case of [6], the control circuit 10B is in a state in which it cannot output the normal second output voltage V2 in response to the second control signal S2, that is, the control circuit 10B is not operating normally. In this case, two signals S1 and /S2 of the three signals S1, /S2, /V2 input to the AND circuit 31 of the output determination circuit 30 are at the low level. Therefore, the AND circuit 31 outputs the first output voltage V1 which is at the low level. Since the first control signal S1 is at the low level, the first output voltage V1 to be at the low level itself is a normal operation.

On the other hand, in the case of [6], the second output voltage V2 of the three signals /S1, S2, and V2 input to the AND circuit 41 in the fault determination circuit 40 is at the low level. Therefore, the output of the AND circuit 41 is at the low level. In the case of [6], the second control signal /S2 of the three signals /S1, /S2, and /V2 input to the AND circuit 42 in the fault determination circuit 40 is at the low level. Therefore, the output of the AND circuit 42 is also at the low level. In addition, the first output voltage V1 input from the AND circuit 31 of the output determination circuit 30 to the NOR circuit 43 is also at the low level. Therefore, the fault signal FS1 output from the NOR circuit 43 is at the high level. Thus, the fault signal /FS1 output from the fault output terminal 11c is at the low level. In other words, the state of the fault signal /FS1 is a state indicating that an abnormality has been detected.

As described above, in the case of [6] in Table 1, the determination circuit 20 determines through the abnormality determination operation that at least one of the control state of the switching device 61 and the control state of the switching device 62 is abnormal. Thus, the control circuit 10A outputs the fault signal /FS1 which is at the low level indicating an abnormal state. The control circuit 10A outputs the first output voltage V1 which is at the low level, which is a normal output, on the basis of the first control signal S1 being at the low level. In this case, since the two switching devices 61 and 62 are in the OFF state, the bridge circuit 60 is protected.

For the other cases of [3], [4], [5], [7], and [8] in Table 1, the control circuit 10A performs the abnormality determination operation by the determination circuit 20 in the same manner as for the cases of [1], [2], and [6], and outputs the first output voltage V1 and the fault signal /FS1 on the basis of the determination result.

As shown in FIG. 1, in the control circuit 10B of the second drive device 82, the second control signal S2 is input to the first input terminal 11a via a resistor element R1b, and the first control signal S1 is input to the second input terminal 11b via a resistor element R2b. In the control circuit 10B, the second output voltage V2 is output from the output terminal 11f. The output terminal 11f of the control circuit 10B is connected to the gate terminal of the switching device 62 via a resistor element R5b. Thus, the second output voltage V2 is applied to the gate terminal of the switching device 62. A positive power supply voltage VCC2 is applied to the positive power supply terminal 11e of the control circuit 10B by a power supply E2. The positive power supply voltage VCC2 may be the same as or different from the positive power supply voltage VCC1. A negative power supply voltage VEE2 is applied to the negative power supply terminal 11h of the control circuit 10B by the power supply E2. The negative power supply voltage VEE2 may be the same as or different from the negative power supply voltage VEE1. In the control circuit 10B, a capacitor C2 is disposed between the positive power supply terminal lie and the negative power supply terminal 11h.

The first output voltage /V1 is input to the third input terminal 11g of the control circuit 10B. The first output voltage /V1 is a voltage that is output from the isolator 83b on the basis of the first output voltage V1 output from the output terminal 11f of the control circuit 10A. The first output voltage /V1 is a negative logic signal that is at the low level when the first output voltage V1 is at the high level and is at the high level when the first output voltage V1 is at the low level. That is, the first output voltage V1 is inverted via the isolator 83b and is input to the third input terminal 11g of the control circuit 10B as the first output voltage /V1. In the first embodiment, the first output voltage /V1 corresponds to “device information” indicating the state of the switching device 61. Since the first output voltage V1 output from the output terminal 11f of the control circuit 10A is applied to the gate terminal of the switching device 61, the state of the switching device 61 can be grasped from a value of the first output voltage /V1 on the basis of the first output voltage V1. In the first embodiment, the first output voltage /V1 is information based on the gate voltage (the drive voltage) applied to the switching device 61.

The isolator 83b is an optical coupler having a light emitting diode and a phototransistor. The first output voltage V1 output from the output terminal 11f of the control circuit 10A is input to the isolator 83b. A resistor element R6a is disposed between the input terminal of the isolator 83b and the output terminal 11f of the control circuit 10A. A resistor element R4b is disposed between the output terminal of the isolator 83b and the positive power supply terminal 11e of the control circuit 10B. When the input first output voltage V1 is at the high level, the isolator 83b inputs the first output voltage /V1 which is at the low level to the third input terminal 11g of the control circuit 10B. When the input first output voltage V1 is at the low level, the isolator 83b inputs the first output voltage /V1 which is at the high level to the third input terminal 11g of the control circuit 10B. The control circuit 10B performs an abnormality determination operation as in the control circuit 10A, except that the control circuit 10B uses the first output voltage /V1 instead of the second output voltage /V2, and the output from the output terminal 11f is the second output voltage V2.

The semiconductor circuit 100 includes an overcurrent detection circuit 12. The overcurrent detection circuit 12 includes a resistor element 12a and a logic gate 12b. One end of the resistor element 12a is connected to the source terminal of the switching device 62. The other end of the resistor element 12a is connected to a wire to which the negative power supply voltage VEE2 is applied. The voltage at the source terminal of the switching device 62 and the negative power supply voltage VEE2 are applied to the logic gate 12b. The logic gate 12b outputs a fault signal /FS1 to the controller 90. The logic gate 12b outputs the fault signal /FS1 which is at the low level when a value of a current flowing through the resistor element 12a is equal to or greater than a predetermined value, and outputs the fault signal /FS1 which is at the high level when the value of the current flowing through the resistor element 12a is smaller than the predetermined value. Thus, even when the two switching devices 61 and 62 are short-circuited and an overcurrent flows through the two switching devices 61 and 62, the fault signal /FS1 indicating an abnormality is input from the overcurrent detection circuit 12 to the controller 90. Therefore, on the basis of the fault signal /FS1 transmitted from the overcurrent detection circuit 12, the controller 90 can send a signal to the control circuits 10A and 10B to set at least one of the two switching devices 61 and 62 to the OFF state, thereby protecting the bridge circuit 60. Although not shown, the fault signal /FS1 output from the logic gate 12b may be output to the controller 90 via an insulation signal transmission device other than the insulation transmission device 50.

According to the first embodiment, the control circuit 10A is a control circuit provided in the drive circuit 80 that is configured to drive the bridge circuit 60 having the plurality of switching devices 61 and 62 by controlling the plurality of switching devices 61 and 62 respectively using the plurality of control circuits 10A and 10B. The control circuit 10A is configured such that the first control signal S1 for controlling the switching device 61 (the first switching device) that is controlled by the control circuit 10A itself among the plurality of switching devices 61 and 62, and a second control signal S2 for controlling the switching device 62 (the second switching device) that is controlled by the other control circuit 10B among the plurality of switching devices 61 and 62 are input to the control circuit 10A. Therefore, the control circuit 10A can compare the first control signal S1 for controlling the switching device 61 controlled by the control circuit 10A itself with the second control signal S2 for controlling the switching device 62 controlled by the other control circuit 10B. Thus, the control circuit 10A can grasp whether or not an abnormality has occurred in at least one of the control signals that control the two switching devices 61 and 62. Therefore, for example, the control circuit 10A can determine that an abnormality has occurred when both the first control signal S1 and the second control signal S2 are at the high level, and can set the switching device 61 that is controlled by the control circuit 10A itself to the OFF state regardless of the state of the first control signal S1. As a result, it is possible to curb the two switching devices 61 and 62 being short-circuited to each other, and to curb an overcurrent flowing through the bridge circuit 60. Thus, it is possible to curb the switching devices 61 and 62 being damaged.

Furthermore, in the past, for example, the bridge circuit 60 was protected by detecting a short circuit between the two switching devices 61 and 62 only with the above-described overcurrent detection circuit 12. In this case, however, there is a problem that it is not possible to detect the occurrence of an abnormality in at least one of the control states of the two switching devices 61 and 62 until the two switching devices 61 and 62 are short-circuited to each other and an overcurrent flows through the resistor element 12a. On the other hand, according to the first embodiment, by comparing the two control signals for controlling the two switching devices 61 and 62, it is possible to detect a possibility of the two switching devices 61 and 62 being short-circuited to each other before an overcurrent occurs in the control circuit 10A. Therefore, the control circuit 10A can determine that an abnormality has occurred and can set the switching device 61 to the OFF state before the two switching devices 61 and 62 are actually short-circuited to each other. Thus, it is possible to more effectively curb an overcurrent flowing through the bridge circuit 60. According to the first embodiment, an abnormality can be detected faster, for example, by about 10 ns (nanoseconds) or more and several hundred ns (nanoseconds) or less, compared to a case in which the abnormality detection is performed using only the overcurrent detection circuit 12.

In addition, since the first control signal S1 and the second control signal S2 are input to the control circuit 10A as two control signals for controlling the two switching devices 61 and 62, it is also possible to determine whether or not an abnormality occurs in a dead time in which the two switching devices 61 and 62 are in the OFF state by comparing the state of the first control signal S1 with the state of the second control signal S2.

According to the first embodiment, the control circuit 10A is configured to perform an abnormality determination operation for determining whether or not an abnormality has occurred in at least one of the control state of the switching device 61 and the control state of the switching device 62. The control circuit 10A is configured such that the second output voltage /V2 is input to the control circuit 10A as the device information indicating the state of the other switching device 62. The abnormality determination operation includes determining whether or not an abnormality has occurred in at least one of the control state of the switching device 61 and the control state of the switching device 62 on the basis of the first control signal S1, the second control signal S2, and the second output voltage /V2 (the device information). Therefore, when the first control signal S1 and the second control signal S2 are normal, even when the switching device 62 malfunctions due to some reason, the control circuit 10A can detect that the state of the switching device 62 is abnormal on the basis of the second output voltage /V2. Thus, the control circuit 10A can quickly detect an abnormality in which the switching device 62 is in the ON state when the second control signal S2 is at the low level, for example, and can quickly set the switching device 61 to the OFF state. Therefore, damage to the two switching devices 61 and 62 can be further curbed. An example of the case in which the switching device 62 malfunctions due to some reason is a case in which Self turn-on of the switching device 62 occurs on due to a miller current generated by a switching operation of the other switching device 61, thus the gate voltage of the switching device 62 rises, and the second output voltage V2 is at the high level.

According to the first embodiment, the device information indicating the state of the other switching device 62 includes information based on the gate voltage (the drive voltage) applied to the other switching device 62, that is, the second output voltage V2. Therefore, on the basis of this information, the control circuit 10A can more easily and accurately detect the state of the switching device 62. In the first embodiment, this information is the second output voltage /V2.

According to the first embodiment, the abnormality determination operation includes determining whether or not the two switching devices 61 and 62 will be in an ON state concurrently. The control circuit 10A is configured to set the switching device 61 to an OFF state when it is determined in the abnormality determination operation that the two switching devices 61 and 62 will be in the ON state concurrently. Therefore, it is possible to curb the two switching devices 61 and 62 being short-circuited to each other, and it is possible to suitably curb the switching devices 61 and 62 being damaged. In the first embodiment, in the cases of [2] and [3] in Table 1, the control circuit 10A determines that the two switching devices 61 and 62 will be in the ON state concurrently. Therefore, in the cases of [2] and [3], the control circuit 10A outputs the first output voltage V1 which is at the low level and sets the switching device 61 to the OFF state.

According to the first embodiment, the control circuit 10A is configured to output a signal which indicates that an abnormality has occurred when it is determined in the abnormality determination operation that an abnormality has occurred in at least one of the control state of the switching device 61 and the control state of the switching device 62. Specifically, the control device 10A is configured to output the fault signal /FS1 which is at the low level when it is determined in the abnormality determination operation that an abnormality has occurred in at least one of the control state of the switching device 61 and the control state of the switching device 62. Therefore, when an abnormality occurs in at least one of the control state of the switching device 61 and the control state of the switching device 62, the control circuit 10A can input the occurrence of the abnormality to the controller 90 using the fault signal /FS1. The control circuit 10A is configured to output a signal which indicates that an abnormality has occurred when it is determined in the abnormality determination operation that an abnormality has occurred in the control state of the switching device 61. The control circuit 10A is configured to output a signal which indicates that an abnormality has occurred when it is determined in the abnormality determination operation that an abnormality has occurred in the control state of the switching device 62. The control circuit 10A is configured to output a signal which indicates that an abnormality has occurred when it is determined in the abnormality determination operation that an abnormality has occurred in both the control state of the switching device 61 and the control state of the switching device 62.

The effects obtained by the control circuit 10A described above can also be obtained by the control circuit 10B.

According to the first embodiment, the drive circuit 80 is a drive circuit which is configured to drive the bridge circuit 60 having the two switching devices 61 and 62 connected to each other. The drive circuit 80 includes the two control circuits 10A and 10B. The two control circuits 10A and 10B are configured to control the two switching devices 61 and 62, respectively. Therefore, the control circuit 10A and the control circuit 10B can monitor each other's control signal input to the other's control circuit and the output voltage output from the other's control circuit, and can each perform the abnormality determination operation as described above. Thus, the drive circuit 80 having the two control circuits 10A and 10B can detect its own malfunction. Therefore, the drive circuit 80 can detect an abnormality occurring in the bridge circuit 60 earlier than in the conventional case in which the abnormality is detected by an external circuit such as the overcurrent detection circuit 12. Therefore, the bridge circuit 60 can be protected more quickly, and damage to the switching devices 61 and 62 can be further curbed.

### Second Embodiment

A second embodiment is different from the first embodiment in the configuration of control circuits 210A and 210B. In the following description, the same components as those in the above-described embodiments may be denoted by the same reference numerals as appropriate, and descriptions thereof may be omitted.

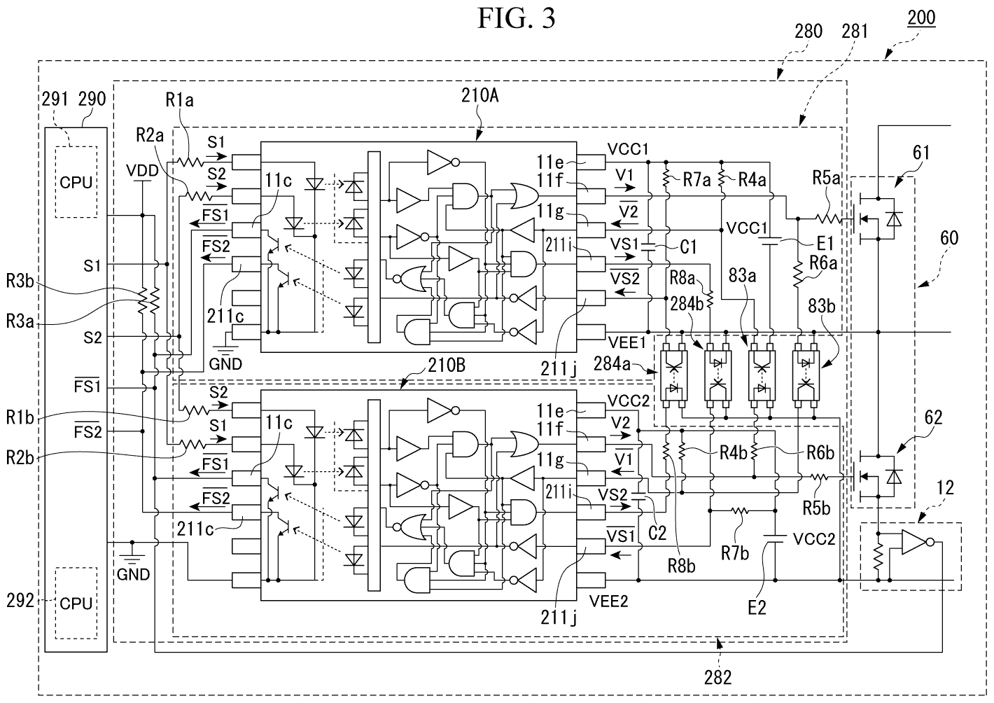

FIG. 3 is a circuit diagram showing a semiconductor circuit 200 according to the second embodiment. As shown in FIG. 3, a controller 290 of the semiconductor circuit 200 includes two CPUs 291 and 292. Each of the CPUs 291 and 292 has the same configuration as the CPU 91 of the first embodiment. For example, when both the two CPUs 291 and 292 are operating normally, the controller 290 controls a drive circuit 280 through the CPU 291, and when the CPU 291 fails, the controller 290 controls the drive circuit 280 through the CPU 292. The controller 290 may, for example, control a first drive device 281 of the drive circuit 280 by the CPU 291 and control a second drive device 282 of the drive circuit 280 by the CPU 292. In this case, when one of the two CPUs 291 and 292 fails, the other CPU may control both the first drive device 281 and the second drive device 282.

The drive circuit 280 has a first drive device 281 that drives the switching device 61, a second drive device 282 that drives the switching device 62, and isolators 83a, 83b, 284a, and 284b. The first drive device 281 and the second drive device 282 have the same configuration except that they drive different switching devices. Therefore, in the following description, the first drive device 281 will be described as an example, and a description of the second drive device 282 may be omitted. The first drive device 281 has a control circuit 210A. The second drive device 282 has a control circuit 210B. In the following description, the control circuit 210A will be described as an example of the control circuits 210A and 210B, and a description of the control circuit 210B may be omitted.

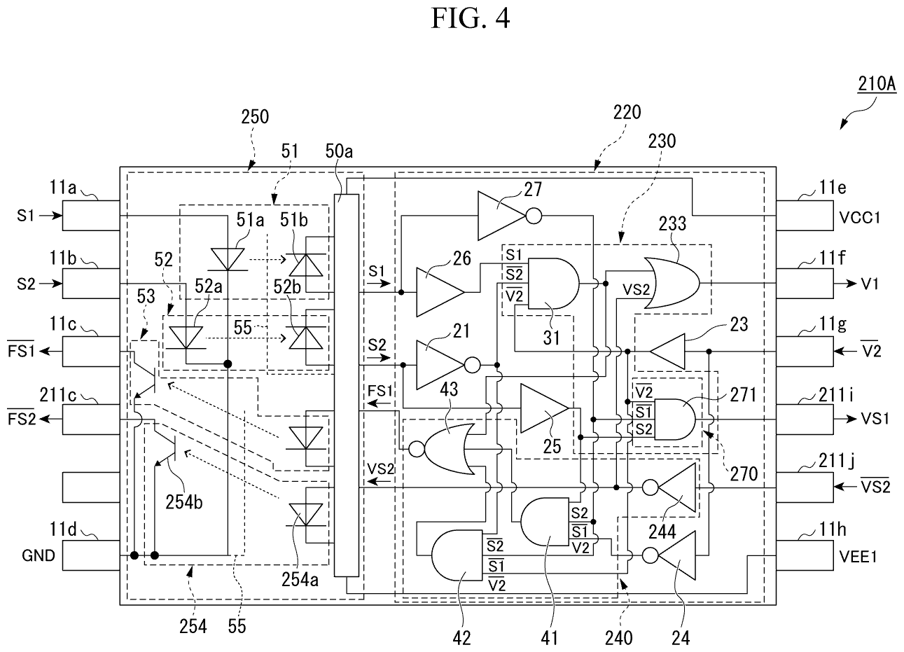

FIG. 4 is a circuit diagram showing the control circuit 210A according to the second embodiment. As shown in FIG. 4, the control circuit 210A includes a first input terminal 11a, a second input terminal 11b, a fault output terminal 11c, a ground terminal 11d, a positive power supply terminal 11e, an output terminal 11f, a third input terminal 11g, a negative power supply terminal 11h, a second fault output terminal 211c, a second output terminal 211i, a fourth input terminal 211j, a determination circuit 220, and an insulation transmission device 250.

The second fault output terminal 211c is a terminal that outputs a second fault signal /FS2. The second fault signal /FS2 is input to the controller 290. The second fault signal /FS2 is a signal that changes on the basis of a determination result of an abnormality determination operation. The second fault signal /FS2 changes according to a state of an enable signal /VS2 which will be described below. The second fault signal /FS2 is at a high level when the enable signal /VS2 is at the high level, and is at a low level when the enable signal /VS2 is at the low level. As shown in FIG. 3, a resistor element R3b is disposed between the second fault output terminal 211c and a power supply terminal of terminals of the controller 290 to which a positive power supply voltage VDD is applied.

The second output terminal 211i is a terminal that outputs an enable signal VS1. The enable signal VS1 is a signal for setting the switching device 62 controlled by the other control circuit 210B to an ON state. The enable signal VS1 is input to the isolator 284b via a resistor element R8a. The enable signal VS1 is inverted by being transmitted in an insulated manner in the isolator 284b to become an enable signal /VS1, which is input to the fourth input terminal 211j of the control circuit 210B. The isolator 284b has the same configuration as the isolator 83b. A resistor element R7b is disposed between the output terminal of the isolator 284b and the positive power supply terminal 11e of the control circuit 210B. In a case in which the enable signal VS1 is at the high level, that is, the enable signal /VS1 is at the low level, when the enable signal /VS1 is input to the control circuit 210B, the second output voltage V2 output from the control circuit 210B is at the high level, and the switching device 62 is in an ON state.

An enable signal /VS2 is input to the fourth input terminal 211j of the control circuit 210A. The enable signal /VS2 is input from the control circuit 210B to the control circuit 210A via the isolator 284a. The enable signal /VS2 is a signal obtained by inverting the enable signal VS2 output from the second output terminal 211i of the control circuit 210B by the isolator 284a. The enable signal VS2 is a signal output from the other control circuit 210B, and is a signal for setting the switching device 61 controlled by the control circuit 210A to an ON state. The enable signal VS2 output from the second output terminal 211i is input to the isolator 284a via a resistor element R8b. The enable signal VS2 is inverted by being transmitted in an insulated manner in the isolator 284a to become an enable signal /VS2, which is input to the fourth input terminal 211j of the control circuit 210A. The isolator 284a has the same configuration as the isolator 83a. A resistor element R7a is disposed between the output terminal of the isolator 284a and the positive power supply terminal 11e of the control circuit 210A. In a case in which the enable signal VS2 is at the high level, that is, the enable signal /VS2 is at the low level, when the enable signal /VS2 is input to the control circuit 210A, the first output voltage V1 output from the control circuit 210A is at the high level, and the switching device 61 is in the ON state.

As shown in FIG. 4, the insulation transmission device 250 includes a first transmission device 51, a second transmission device 52, a third transmission device 53, a fourth transmission device 254, a shielding film 55, and a conversion circuit 50a. The fourth transmission device 254 transmits, in an insulated manner, the enable signal VS2 input from a NOT circuit 244 (described below) of the determination circuit 220 to the second fault output terminal 211c. The fourth transmission device 254 is an optical coupler having a light emitting diode 254a and a phototransistor 254b. The structure of the fourth transmission device 254 is the same as the structure of the third transmission device 53. The enable signal VS2 output from the NOT circuit 244 is inverted by the fourth transmission device 254 and is output as a second fault signal /FS2 from the second fault output terminal 211c to the controller 290. The other configurations of the insulation transmission device 250 are similar to the other configurations of the insulation transmission device 50 in the first embodiment.

The determination circuit 220 includes an output determination circuit 230 and a fault determination circuit 240. In the second embodiment, the output determination circuit 230 includes an AND circuit 31, an OR circuit 233, and an enable output determination circuit 270. Two signals including an output from the AND circuit 31 and the enable signal VS2 inverted by the NOT circuit 244 of the fault determination circuit 240 are input to the OR circuit 233. The OR circuit 233 outputs a first output voltage V1 to the output terminal 11f on the basis of the two input signals. The OR circuit 233 is configured to output the first output voltage V1 which is at the high level when at least one of the output from the AND circuit 31 and the enable signal VS2 is at the high level. The OR circuit 233 is configured to output the first output voltage V1 which is at the low level when both the output from the AND circuit 31 and the enable signal VS2 are at the low level.

The enable output determination circuit 270 is configured to change the state of the enable signal VS1 that it outputs on the basis of the first control signal /S1, the second control signal S2, and the second output voltage /V2. The enable output determination circuit 270 includes an AND circuit 271. Three signals including the first control signal /S1 inverted via the NOT circuit 27, the second control signal S2 input via a buffer circuit 25, and the second output voltage /V2 input via a buffer circuit 23 are input to the AND circuit 271. The AND circuit 271 is configured to output an output signal which is at the high level when all the three input signals are at the high level. The AND circuit 271 is configured to output the output signal which is at the low level when at least one of the three input signals is at the low level. The output signal output from the AND circuit 271 is output to the second output terminal 211i as the enable signal VS1. The other configurations of the output determination circuit 230 are similar to the other configurations of the output determination circuit 30 of the first embodiment.

In the second embodiment, the fault determination circuit 240 is configured to determine whether the level of the fault signal /FS1 and the level of the second fault signal /FS2 should be the high level or the low level. The fault determination circuit 240 includes an AND circuit 41, an AND circuit 42, a NOR circuit 43, and a NOT circuit 244. The enable signal /VS2 is input to the NOT circuit 244. The NOT circuit 244 inverts the enable signal /VS2 and outputs it as the enable signal VS2. The enable signal VS2 is input to the insulation transmission device 250 and the OR circuit 233. When the enable signal VS2 is at the high level, the light emitting diode 254a of the fourth transmission device 254 emits light, and the phototransistor 254b is in an ON state. Thus, the second fault signal /FS2 output from the second fault output terminal 211c is at the low level. That is, the second fault signal /FS2 is in state indicating an abnormality. When the enable signal VS2 is at the low level, the second fault signal /FS2 output from the second fault output terminal 211c is at the high level. Other configurations of the fault determination circuit 240 are similar to those of the fault determination circuit 40 of the first embodiment.

Table 2 shows the first control signal S1, the second control signal S2, the second output voltage /V2, the enable signal VS1, the first output voltage V1, the fault signal /FS1, and the determination result of the abnormality determination operation in the second embodiment.

TABLE 2

| | Level of | Level of | Level of | | Level of | | |
|---|---|---|---|---|---|---|---|
| | first | second | second | Level of | first | Level of | |
| | control | control | output | enable | output | fault | |
| | signal | signal | voltage | signal | voltage | signal | Determination |
| No. | S1 | S2 | V̅2̅ | VS1 | V1 | F̅S̅1̅ | result |
| [1] | High | Low | High | Low | High | High | Pass |
| | | | (Normality) | (Normality) | (Normality) | | |
| [2] | High | High | Low | Low | High | Low | Fail |
| | | (Input | (Output | (Abnormality: | →Low | | |
| | | abnormality) | normality) | Low fixed) | (Protection) | | |
| [3] | High | Low | Low | Low | High | Low | Fail |
| | | | (Output | (Abnormality: | →Low | | |
| | | | abnormality) | Low fixed) | (Protection) | | |
| [4] | High | High | High | Low | High | Low | Fail |
| | | (Input | (Not | (Abnormality: | →Low | | |
| | | abnormality) | operating) | Low fixed) | | | |
| [5] | Low | High | Low | Low | Low | High | Pass |
| | | | (Normality) | (Normality) | (Normality) | | |
| [6] | Low | High | High | High | Low | Low | Fail |
| | | | (Not | (Abnormality: | (Normality) | | |
| | | | operating) | Pair output | | | |
| | | | | High) | | | |
| [7] | Low | Low | High | Low | Low | High | Pass |
| | | | (Normality) | (Normality) | (Normality) | | |
| [8] | Low | Low | Low | Low | Low | Low | Fail |
| | | | (Output | (Abnormality: | (Normality) | | |
| | | | abnormality) | Low fixed) | | | |

The combinations of the first control signal S11, the second control signal S2, and the second output voltage /V2 of [1] to [8] in Table 2 are similar to the combinations of the first control signal S1, the second control signal S2, and the second output voltage /V2 of [1] to [8] in Table 1 of the first embodiment. The items in Table 2 other than the enable signal VS1 are similar to those in Table 1.

For example, in [1] of Table 2 which is normal, two signals /S1 and S2 of the three signals /S1, S2 and /V2 input to the AND circuit 271 of the enable output determination circuit 270 are at the low level. Therefore, the output of the AND circuit 271 is at the low level, and the enable signal VS1 is at the low level.

For example, in [2] of Table 2 in which an abnormality occurs in the input control signal, two signals /S1 and /V2 of the three signals /S1, S2, and /V2 input to the AND circuit 271 of the enable output determination circuit 270 are at the low level. Therefore, the output of the AND circuit 271 is at the low level, and the enable signal VS1 is at the low level. In this case, an abnormality has occurred, but since it is an input abnormality that causes the control signal to become abnormal, the enable signal VS1 is fixed to be at the low level.

For example, in [6] of Table 2, since the second control signal S2 is at the high level, in a normal state, the second output voltage V2 should also be at the high level and the second output voltage /V2 should be at the low level. However, in the case of [6], the second output voltage /V2 is at the high level, and the control circuit 210B does not operate normally. Thus, the other switching device 62 is not in the normal state. In this case, all the three signals /S1, S2, and /V2 input to the AND circuit 271 of the enable output determination circuit 270 are at the high level. Therefore, the output of the AND circuit 271 is at the high level, and the enable signal VS1 is at the high level. Thus, the enable signal /VS1 input to the fourth input terminal 211j of the control circuit 210B is at the low level, and the high level enable signal VS1 inverted by the NOT circuit 244 is input to the OR circuit 233 of the control circuit 210B. Therefore, the output of the OR circuit 233 in the control circuit 210B, which had been low, is transitioned to the high level, and the second output voltage V2 output from the control circuit 210B is transitioned to the high level. Thus, the switching device 62 can be switched to the normal state.

In this way, in the second embodiment, the determination circuit 220 determines whether or not the state of the other switching device 62 is normal on the basis of the first control signal S1, the second control signal S2, and the second output voltage /V2, and when it is determined that the state of the other switching device 62 is not normal, the determination circuit 220 outputs a signal for setting the other switching device 62 to the normal state, that is, an enable signal VS1. When the enable signal /VS1 is at the low level in the control circuit 210B, the second fault signal /FS2 output from the second fault output terminal 211c of the control circuit 210B is at the low level. Therefore, the state of the switching device 62 is switched to the normal state by the enable signal /VS1 input from the control circuit 210A, and a second fault signal /FS2 indicating that a control state of the switching device 62 in the control circuit 210B is abnormal is input to the controller 290.

The other configurations of the control circuit 210A are similar to those of the control circuit 10A of the first embodiment. The control circuit 210B is similar to the control circuit 210A, except that the signals input and output differ as appropriate due to the different switching devices that are controlled. The other configurations of the semiconductor circuit 200 are similar to the other configurations of the semiconductor circuit 100 of the first embodiment.

According to the second embodiment, the abnormality determination operation in the control circuit 210A includes determining whether or not the state of the other switching device 62 is in a normal state on the basis of the first control signal S1, the second control signal S2, and the second output voltage /V2 (the device information). The control circuit 210A is configured such that when it is determined in the abnormality determination operation that the state of the other switching device 62 is not in the normal state, the control circuit 210A outputs the enable signal VS1 for setting the state of the other switching device 62 to the normal state. Therefore, when the switching device 62 controlled by the other control circuit 210B is not operating normally, the state of the other switching device 62 can be switched to the normal state by the control circuit 210A. Therefore, even when an abnormality occurs, the operation of the bridge circuit 60 can be continued.

According to the second embodiment, the control circuit 210A is configured to output the signal for setting the state of the other switching device 62 to the normal state to the control circuit 210B that controls the other switching device 62. Therefore, the control circuit 210A can operate the control circuit 210B by the signal, and switch the state of the other switching device 62 to the normal state. Specifically, in the second embodiment, when the other switching device 62 is in the OFF state at a timing when it should be in the ON state, the control circuit 210A outputs the enable signal VS1 for setting the state of the switching device 62 to the ON state to the control circuit 210B. Thus, the second output voltage V2 for setting the state of the switching device 62 to the ON state is output from the control circuit 210B, and the state of the switching device 62 becomes the ON state.

The effects obtained by the control circuit 210A described above can also be obtained by the control circuit 210B.

In the above example, although the example in which when the other switching device 62 is in the OFF state at a timing when it should be in the ON state, the enable signal VS1 for setting the state of the other switching device 62 to the ON state is output from one control circuit 210A has been described, the present embodiment is not limited thereto. For example, when the other switching device 62 is in the ON state at a timing when it should be in the OFF state, a disable signal for setting the state of the other switching device 62 to the OFF state may be output from the one control circuit 210A. The same applies to the control circuit 210B. For example, when the disable signal output from the control circuit 210A is at the high level, the state of the switching device 62 controlled by the control circuit 210B is switched to the OFF state. In this case, the disable signal is at the high level in the cases of [2], [3], and [8] of Table 2, and is at the low level in the cases of [1], [4], [5], [6], and [7].

### Third Embodiment

A third embodiment is different from the second embodiment in that a buffer drive circuit 385 is provided. In the following description, the same components as those in the above-described embodiment may be denoted by the same reference numerals as appropriate, and descriptions thereof may be omitted.

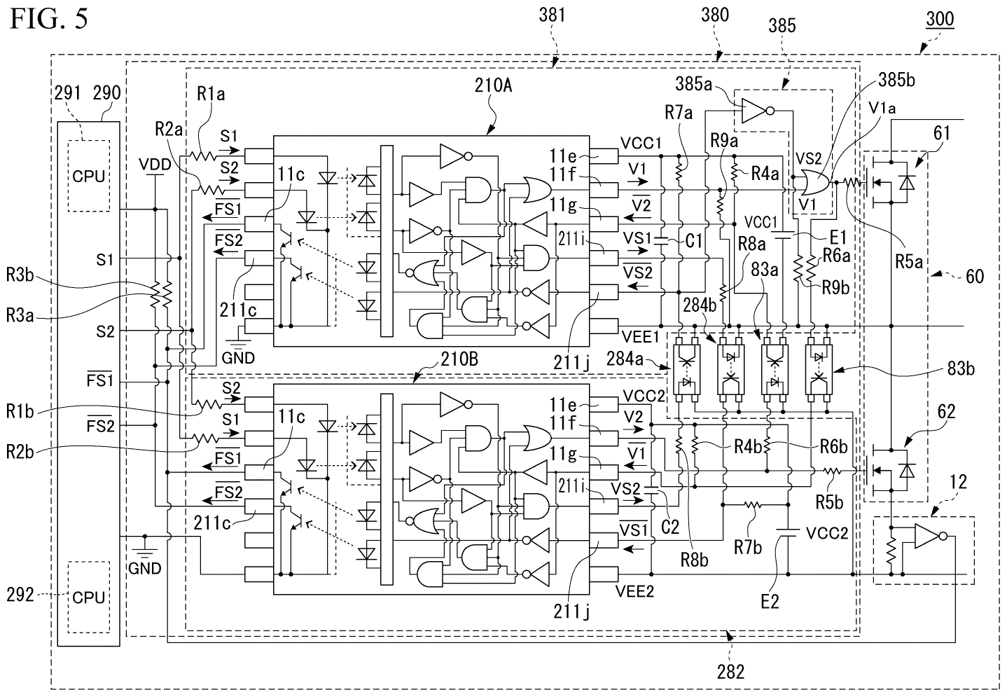

FIG. 5 is a circuit diagram showing a semiconductor circuit 300 according to the third embodiment. As shown in FIG. 5, a drive circuit 380 of the semiconductor circuit 300 includes a buffer drive circuit 385. In this embodiment, the buffer drive circuit 385 is provided in a first drive device 381. The first drive device 381 is similar to the first drive device 281 in the second embodiment, except that it has the buffer drive circuit 385. The buffer drive circuit 385 includes a NOT circuit 385a and an OR circuit 385b. The NOT circuit 385a is configured to invert the enable signal /VS2 input from the isolator 284a to the fourth input terminal 211j and input it to the OR circuit 385b as the enable signal VS2.

The OR circuit 385b is disposed between the output terminal 11f of the control circuit 210A and the resistor element R5a. The enable signal VS2 inverted by the NOT circuit 385a and the first output voltage V1 output from the output terminal 11f are input to the OR circuit 385b. The OR circuit 385b is configured to output a first output voltage V1a to the gate terminal of the switching device 61 on the basis of the enable signal VS2 and the first output voltage V1. The OR circuit 385b is configured to output the first output voltage V1a which is at a high level when at least one of the enable signal VS2 and the first output voltage V1 is at the high level. The OR circuit 385b is configured to output the first output voltage V1a which is at a low level when both the enable signal VS2 and the first output voltage V1 are at the low level. In the third embodiment, a resistor element R9a is disposed between the output terminal 11f and a wire to which the negative power supply voltage VEE1 is applied. A resistor element R9b is disposed between an output-side terminal of the NOT circuit 385a and the wire to which the negative power supply voltage VEE1 is applied.

For example, when the control circuit 210A stops due to a malfunction or the like, the first output voltage V1 output from the output terminal 11f of the control circuit 210A is always at the low level. In this case, since the first output voltage /V1 input to the control circuit 210B is at the high level, at a timing when the switching device 61 is in the ON state in the normal state, the enable signal VS2 output from the control circuit 210B is at the high level, and the enable signal /VS2 input to the control circuit 210A via the isolator 284a is at the low level. When the control circuit 210A is operating, the state of the switching device 61 can be switched to the ON state by the enable signal /VS2 input to the control circuit 210A, as described in the second embodiment. However, since the control circuit 210A is not operating, the first output voltage V1 output from the control circuit 210A is not at the high level, and the switching device 61 cannot be in the ON state. On the other hand, in the third embodiment, the enable signal /VS2 output from the control circuit 210B is also input to the buffer drive circuit 385. When the enable signal VS2 inverted by the NOT circuit 385a is at the high level, the buffer drive circuit 385 outputs the first output voltage V1a, which is at the high level, applied to the switching device 61. Thus, even when the control circuit 210A is stopping, the state of the switching device 61 can be the ON state by the control circuit 210B.

In this way, according to the third embodiment, the control circuit 210B is configured to control the switching device 61 controlled by the other control circuit 210A instead of the other control circuit 210A when the other control circuit 210A stops. Therefore, even when the control circuit 210A stops, the bridge circuit 60 can continue to be driven.

The above-described buffer drive circuit 385 is a circuit that enables the control circuit 210B to control the switching device 61 when the control circuit 210A stops, but the present embodiment is not limited thereto. The buffer drive circuit 385 may be provided for the control circuit 210B in the same manner as for the control circuit 210A. In this case, even when the control circuit 210B stops, the switching device 62 can be controlled by the control circuit 210A. For example, when the drive circuit 380 includes three or more control circuits, at least one of the three or more control circuits may control a switching device controlled by another control circuit instead of the other control circuit when the other control circuit stops. At least one of the three or more control circuits may control switching devices controlled by the two or more other control circuits instead of the two or more other control circuits when the two or more other control circuits stop.

### Fourth Embodiment

A fourth embodiment is different from the second embodiment in the configuration of the insulation transmission device 450. In the following description, the same components as those in the above-described embodiments may be denoted by the same reference numerals as appropriate, and descriptions thereof may be omitted.

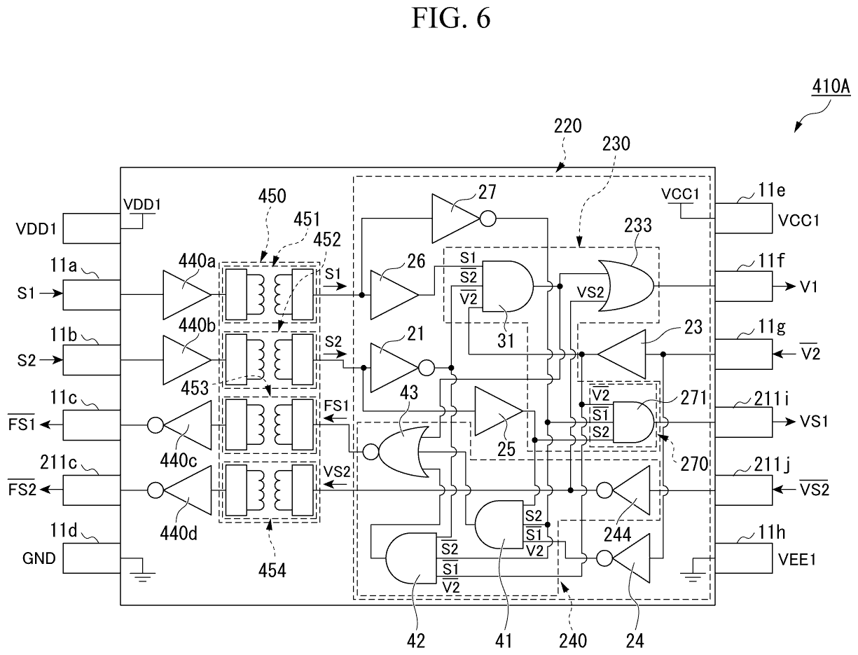

FIG. 6 is a circuit diagram showing a control circuit 410A according to the fourth embodiment. As shown in FIG. 6, an insulation transmission device 450 of the control circuit 410A includes a first transmission device 451, a second transmission device 452, a third transmission device 453, and a fourth transmission device 454. In the fourth embodiment, the first transmission device 451, the second transmission device 452, the third transmission device 453, and the fourth transmission device 454 transmit signals in an insulated manner by magnetic coupling. The first transmission device 451, the second transmission device 452, the third transmission device 453, and the fourth transmission device 454 have the same functions as the first transmission device 51, the second transmission device 52, the third transmission device 53, and the fourth transmission device 254 of the second embodiment described above, respectively, except that a transmission method is different. The first control signal S1 is input to the first transmission device 451 via a buffer circuit 440a. The second control signal S2 is input to the second transmission device 452 via a buffer circuit 440b. A signal output from the third transmission device 453 is inverted by a NOT circuit 440c and is output as a fault signal /FS1 from the fault output terminal 11c. A signal output from the fourth transmission device 454 is inverted by a NOT circuit 440d and is output as a second fault signal /FS2 from the second fault output terminal 211c.

The other configurations of the control circuit 410A are similar to the other configurations of the control circuit 210A in the second embodiment. The isolators 83a, 83b, 284a, and 284b in the above-described embodiment may be isolators that transmit signals in an insulated manner by magnetic coupling, as in the insulation transmission device 450.

### Fifth Embodiment

A fifth embodiment is different from the fourth embodiment in that an input determination circuit 582 is provided. In the following description, the same components as those in the above-described embodiments may be appropriately denoted by the same reference numerals, and descriptions thereof may be omitted.

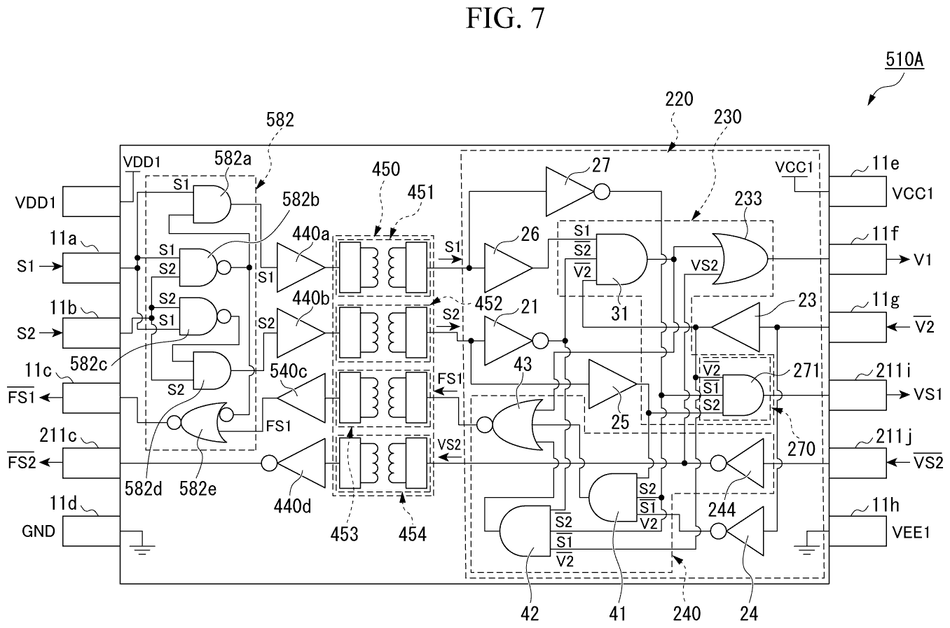

FIG. 7 is a circuit diagram showing a control circuit 510A according to the fifth embodiment. As shown in FIG. 7, the control circuit 510A includes an input determination circuit 582. The input determination circuit 582 is a circuit that is configured to determine whether or not an abnormality occurs in at least one of the first control signal S1 and the second control signal S2 input to the control circuit 510A. The input determination circuit 582 is disposed between the first input terminal 11a and the insulation transmission device 450. The input determination circuit 582 is disposed between the second input terminal 11b and the insulation transmission device 450. The input determination circuit 582 includes AND circuits 582a and 582d, NAND circuits 582b and 582c, and a NOR circuit 582e.

Two signals including the first control signal S1 and an output of the NAND circuit 582b are input to the AND circuit 582a. The AND circuit 582a is configured to output the first control signal S1 that is at a high level when both the two input signals are at the high level. The AND circuit 582a is configured to output the first control signal S1 that is at a low level when at least one of the two input signals is at the low level.

Two signals including the first control signal S1 and the second control signal S2 are input to the NAND circuit 582b. The NAND circuit 582b is configured to output an output signal which is at the low level when both the two input signals are at the high level. The NAND circuit 582b is configured to output the output signal which is at the high level when at least one of the two input signals is at the low level. The output signal of the NAND circuit 582b is input to the AND circuit 582a and the NOR circuit 582e.

Two signals including the first control signal S1 and the second control signal S2 are input to the NAND circuit 582c. The NAND circuit 582c is configured to output an output signal which is at the low level when both the two input signals are at the high level. The NAND circuit 582c is configured to output the output signal which is at the high level when at least one of the two input signals is at the low level. The output signal of the NAND circuit 582c is input to the AND circuit 582d.

Two signals including the second control signal S2 and the output of the NAND circuit 582c are input to the AND circuit 582d. The AND circuit 582d is configured to output the second control signal S2 which is at the high level when both the two input signals are at the high level. The AND circuit 582d is configured to output the second control signal S2 which is at the low level when at least one of the two input signals is at the low level.

The output from the NAND circuit 582b and an output from a buffer circuit 540c are input to the NOR circuit 582e. The output from the buffer circuit 540c is the fault signal FS1 that is output from the NOR circuit 43 of the determination circuit 220 and then is transmitted to the buffer circuit 540c in an insulated manner by the third transmission device 453. The output from the NAND circuit 582b is inverted and input to the NOR circuit 582e. The NOR circuit 582e is configured to output the fault signal /FS1 which is at the low level when at least one of the two input signals is at the high level. The NOR circuit 582e is configured to output the fault signal /FS1 which is at the high level when both the input signals are at the low level.

As described above, each of the NAND circuits 582b and 582c outputs the output signal which is at the low level when both the two input signals are at the high level, and outputs the output signal which is at the high level otherwise. In other words, each of the NAND circuits 582b and 582c is configured to output the output signal which is at the low level only when both the first control signal S1 and the second control signal S2 are at the high level. Since a state in which both the first control signal S1 and the second control signal S2 are at the high level does not occur when the bridge circuit 60 is normally driven, when the NAND circuits 582b and 582c output signals which are at the low level, an abnormality has occurred in the control signal output from the controller 290. Since the outputs from the NAND circuits 582b and 582c are input to the AND circuits 582a and 582d, respectively, when the outputs from the NAND circuits 582b and 582c are at the low level, the signals output from the AND circuits 582a and 582d are also at the low level. Thus, when an abnormality occurs in which both the first control signal S1 and the second control signal S2 are at the high level, both the first control signal S1 and the second control signal S2 are transitioned to the low level by the input determination circuit 582 before they are input to the insulation transmission device 450. Therefore, the input determination circuit 582 can perform the abnormality determination operation before the determination circuit 220 performs the abnormality determination operation, and it is possible to detect that an abnormality has occurred in at least one of the control state of the switching device 61 and the control state of the switching device 62 in the input determination circuit 582. In addition, when it is determined that an abnormality has occurred, the input determination circuit 582 outputs both the first control signal S1 which is at the low level and the second control signal S2 which is at the low level so that the two switching devices 61 and 62 are not simultaneously in the ON state to prevent a short circuit. Therefore, the two switching devices 61 and 62 can be protected more quickly by the control circuit 510A, and it is possible to more suitably curb the two switching devices 61 and 62 being damaged.

As described above, according to the fifth embodiment, the abnormality determination operation performed in the input determination circuit 582 includes determining whether or not an abnormality has occurred in at least one of the control state of the switching device 61 and the control state of the switching device 62 on the basis of the first control signal S1 and the second control signal S2. Therefore, as described above, immediately after the first control signal S1 and the second control signal S2 are input to the first input terminal 11a and the second input terminal 11b, respectively, it is possible to determine whether there is an abnormality in the input control signal by the control circuit 510A, and it is possible to detect the abnormality more quickly by the control circuit 510A. Therefore, it is possible to more suitably curb the two switching devices 61 and 62 being damaged.

When the output from the NAND circuit 582b is at the low level, a signal which is at the high level and is generated by inverting the output from the NAND circuit 582b is input to the NOR circuit 582e. Therefore, regardless of the output from the buffer circuit 540c, the fault signal /FS1 output from the NOR circuit 582e is at the low level. That is, when both the first control signal S1 and the second control signal S2 are at the high level, regardless of the output from the fault determination circuit 240, the fault signal /FS1 output from the fault output terminal 11c is at the low level, which indicates that an abnormality has occurred. Therefore, when an abnormality occurs in which both the first control signal S1 and the second control signal S2 are at the high level, the fault signal /FS1 indicating the occurrence of the abnormality is input to the controller 290.

In the above example, when both the first control signal S1 and the second control signal S2 are at the high level, the input determination circuit 582 determines that an abnormality has occurred in the input and sets the states of the two switching devices 61 and 62 to the OFF state, but the present embodiment is not limited thereto. When an interval between a timing when the first control signal S1 is transitioned to the high level and a timing when the second control signal S2 is transitioned to the high level, that is, a dead time becomes shorter than a set predetermined value, the input determination circuit 582 may determine that an abnormality has occurred in the input and may set the states of the two switching devices 61 and 62 to the OFF state.

### Sixth Embodiment

A sixth embodiment is different from the fourth embodiment in the configuration of the insulation transmission device 650. In the following description, the same components as those in the above-described embodiments may be denoted by the same reference numerals as appropriate, and descriptions thereof may be omitted.

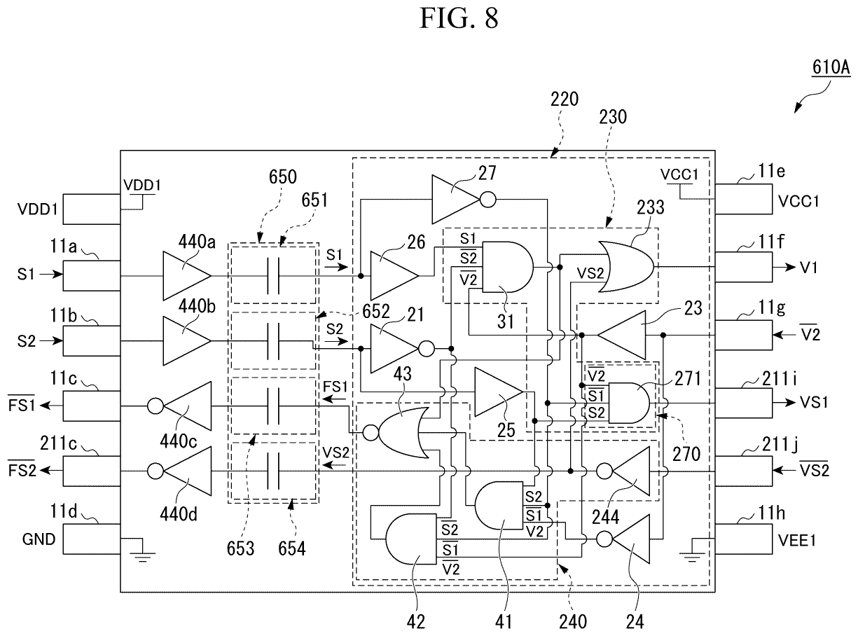

FIG. 8 is a circuit diagram showing a control circuit 610A according to the sixth embodiment. As shown in FIG. 8, an insulation transmission device 650 of the control circuit 610A includes a first transmission device 651, a second transmission device 652, a third transmission device 653, and a fourth transmission device 654. In the sixth embodiment, the first transmission device 651, the second transmission device 652, the third transmission device 653, and the fourth transmission device 654 transmit signals in an insulated manner by capacitive coupling. Each of the first transmission device 651, the second transmission device 652, the third transmission device 653, and the fourth transmission device 654 is a capacitor. The first transmission device 651, the second transmission device 652, the third transmission device 653, and the fourth transmission device 654 have the same functions as the first transmission device 451, the second transmission device 452, the third transmission device 453, and the fourth transmission device 454, respectively, of the fourth embodiment described above, except that the transmission method is different.

The other configuration of the control circuit 610A is similar to the other configuration of the control circuit 410A in the fourth embodiment. The isolators 83a, 83b, 284a, and 284b in the above-described embodiments may be isolators that transmit signals in an insulated manner by capacitive coupling, as in the insulation transmission device 650.

### Seventh Embodiment

The seventh embodiment is different from the fifth embodiment in the configuration of an input determination circuit 782. In the following description, the same components as those in the above-described embodiments may be denoted by the same reference numerals as appropriate, and descriptions thereof may be omitted.

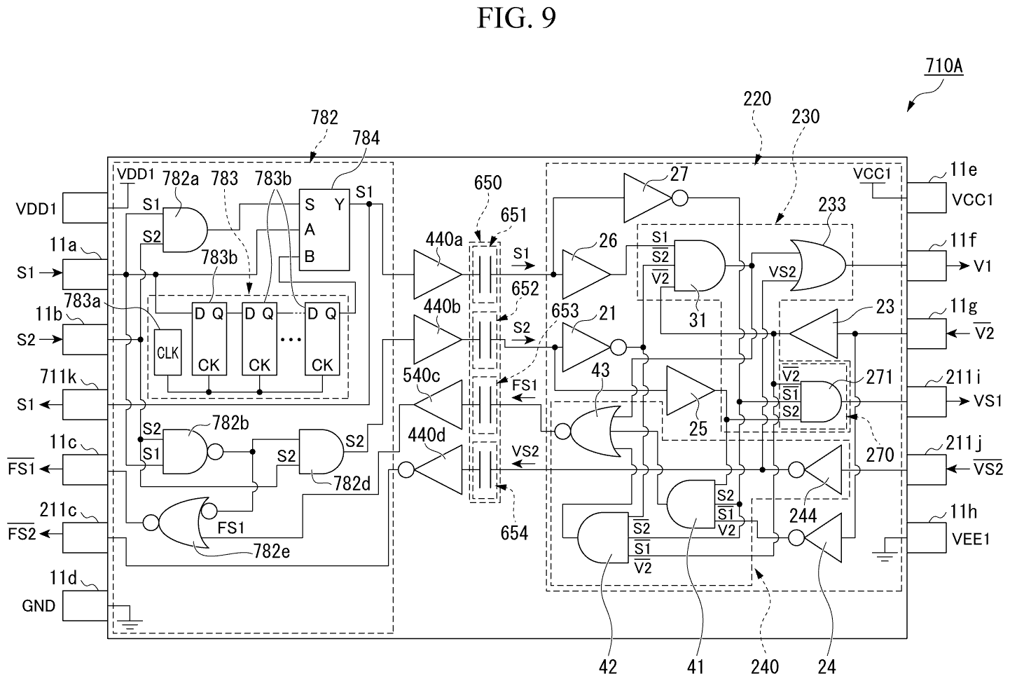

FIG. 9 is a circuit diagram showing a control circuit 710A according to the seventh embodiment. As shown in FIG. 9, an insulation transmission device of the control circuit 710A is the insulation transmission device 650 according to the sixth embodiment. The control circuit 710A has a third output terminal 711k from which the first control signal S1 is output. The first control signal S1 output from the third output terminal 711k is input to a second input terminal 11b of the other control circuit (not shown). In the seventh embodiment, the second control signal S2 input to the second input terminal 11b is the second control signal S2 output from the third output terminal 711k in the other control circuit (not shown).

The input determination circuit 782 of the control circuit 710A includes AND circuits 782a and 782d, a NAND circuit 782b, a NOR circuit 782e, a delay circuit 783, and a switching circuit 784. Two signals including a first control signal S1 and a second control signal S2 are input to the AND circuit 782a. An output signal of the AND circuit 782a is at a high level when both the first control signal S1 and the second control signal S2 are at the high level. An output signal of the AND circuit 782a is at a low level when at least one of the first control signal S1 and the second control signal S2 is at the low level. The output signal of the AND circuit 782a is input to the switching circuit 784 as a set signal.

Two signals including the first control signal S1 and the second control signal S2 are input to the NAND circuit 782b. The NAND circuit 782b is configured to output a signal which is at the low level when both the first control signal S1 and the second control signal S2 are at the high level. The NAND circuit 782b is configured to output the signal which is at the high level when at least one of the first control signal S1 and the second control signal S2 is at the low level.

Two signals including the output from the NAND circuit 782b and the second control signal S2 are input to the AND circuit 782d. The AND circuit 782d is configured to output the second control signal S2 which is the high level when both the two input signals are at the high level. The AND circuit 782d is configured to output the second control signal S2 which is at the low level when at least one of the two input signals is at the low level. The second control signal S2 output from the AND circuit 782d is input to the determination circuit 220 via the buffer circuit 440b and the second transmission device 652.

The output from the NAND circuit 782b and the output from the buffer circuit 540c, that is, the fault signal FS1, are input to the NOR circuit 782e. The output from the NAND circuit 782b is inverted and input to the NOR circuit 782e. The NOR circuit 782e is configured to output the fault signal /FS1 which is at the low level when at least one of the two input signals is at the high level. The NOR circuit 782e is configured to output the fault signal /FS1 which is at the high level when both the two input signals are at the low level.

The delay circuit 783 includes a clock generation circuit 783a and a plurality of D-type flip-flops 783b. The plurality of D-type flip-flops 783b are connected in series. The clock generation circuit 783a inputs a clock signal to the plurality of D-type flip-flops 783b. The first control signal S1 input to the first input terminal 11a is input to the delay circuit 783. The first control signal S1 input to the delay circuit 783 is delayed by the plurality of D-type flip-flops 783b and is input to the switching circuit 784 as a B signal. As the number of D-type flip-flops 783b through which the first control signal S1 input to the delay circuit 783 passes increases, the delay becomes greater. The number of D-type flip-flops 783b through which the first control signal S1 passes may be determined in advance, or may be changed as appropriate according to the control state of the bridge circuit 60, or the like. The number of D-type flip-flops 783b through which the first control signal S1 passes may be changed as appropriate on the basis of the first control signal S1 and the second control signal S2.

The first control signal S1 input to the first input terminal 11a, the output from the AND circuit 782a, and the output from the delay circuit 783 are input to the switching circuit 784. The first control signal S1 from the first input terminal 11a that is input to the switching circuit 784 is input to the switching circuit 784 as an A signal. The switching circuit 784 is a circuit that is configured to switch an output Y between the A signal and the B signal in accordance with an input from the AND circuit 782a that is input as a set signal. When the set signal input from the AND circuit 782a is at the low level, the switching circuit 784 outputs, as the output Y, the A signal, that is, the undelayed first control signal S1 input to the first input terminal 11a. On the other hand, when the set signal input from the AND circuit 782a is at the high level, the switching circuit 784 outputs, as the output Y, the B signal, that is, the delayed first control signal S1 input from the delay circuit 783. The first control signal S1 output from the switching circuit 784 is input to the determination circuit 220 via the buffer circuit 440a and the first transmission device 651, and is also output from the third output terminal 711k to the other control circuit (not shown).

For example, when the first control signal S1 input to the first input terminal 11a is at the high level and the second control signal S2 input to the second input terminal 11b is at the low level, the output from the AND circuit 782a is at the low level, and the undelayed first control signal S1 is output from the switching circuit 784. In this case, the second control signal S2 output from the AND circuit 782d is also at the low level. That is, the first control signal S1 input to the first input terminal 11a and the second control signal S2 input to the second input terminal 11b are input to the determination circuit 220 via the insulation transmission device 650 as they are. This also applies to a case in which the first control signal S1 input to the first input terminal 11a is at the low level and the second control signal S2 input to the second input terminal 11b is at the high level, and a case in which both the first control signal S1 input to the first input terminal 11a and the second control signal S2 input to the second input terminal 11b are at the low level.

On the other hand, when both the first control signal S1 input to the first input terminal 11a and the second control signal S2 input to the second input terminal 11b are at the high level, the output from the AND circuit 782a is at the high level, and the first control signal S1 delayed by the delay circuit 783 is output from the switching circuit 784. In this case, since the output from the NAND circuit 782b is at the low level, the second control signal S2 output from the AND circuit 782d is at the low level even though the second control signal S2 is at the high level. Until the delayed signal input from the delay circuit 783 to the switching circuit 784 is transitioned to the high level, that is, until a time delayed by the delay circuit 783 has elapsed, the first control signal S1 output from the switching circuit 784 is at the low level. Therefore, immediately after both the first control signal S1 and the second control signal S2 which are at the high level are input to the first input terminal 11a and the second input terminal 11b, respectively, both the first control signal S1 and the second control signal S2 which are at the low level are input to the insulation transmission device 650. Then, when the time delayed by the delay circuit 783 has elapsed, the delayed first control signal S1 which is at the high level is output from the switching circuit 784. In other words, a time during which both the first control signal S1 and the second control signal S2 are at the low level can be set to a time during which the first control signal S1 is delayed by the delay circuit 783. The time during which both the first control signal S1 and the second control signal S2 are at the low level is equal to a time during which both the two switching devices 61 and 62 are in the OFF state, that is, the dead time. Therefore, by delaying the first control signal S1 by the delay circuit 783, the dead time can be set to the time during which the first control signal S1 is delayed by the delay circuit 783. In this way, the control circuit 710A of the seventh embodiment can generate the dead time by the delay circuit 783.

When both the first control signal S1 and the second control signal S2 are at the high level, this means that there is no dead time, and thus it is possible to determine whether or not an abnormality has occurred in the dead time by comparing the first control signal S1 and the second control signal S2. That is, the abnormality determination operation performed by the input determination circuit 782 in the seventh embodiment includes determining whether or not an abnormality occurs in the dead time in which both the two switching devices 61 and 62 are in the OFF state. Furthermore, when it is determined in the abnormality determination operation that the input determination circuit 782 determines that both the first control signal S1 and the second control signal S2 are at the high level and that an abnormality occurs in the dead time, the input determination circuit 782 generates a predetermined dead time using the above-described delay circuit 783, and outputs the first control signal S1 and the second control signal S2 based on the generated dead time to the determination circuit 220 via the insulation transmission device 650.

As described above, according to the seventh embodiment, the abnormality determination operation performed by the control circuit 710A includes determining whether or not an abnormality occurs in the dead time in which both the two switching devices 61 and 62 are in the OFF state. The control circuit 710A is configured such that when it is determined in the abnormality determination operation that an abnormality occurs in the dead time, the control circuit 710A generates a predetermined dead time and controls the one switching devices 61 on the basis of the generated dead time. Therefore, even when an abnormality occurs in the dead time, an appropriate dead time can be generated and the two switching devices 61 and 62 can continue to be driven. In addition, it is possible to curb both the two switching devices 61 and 62 being in the ON state, and to curb the two switching devices 61 and 62 being short-circuited to each other. Therefore, it is possible to further curb the two switching devices 61 and 62 being damaged.

In the seventh embodiment, the first control signal S1 output from the switching circuit 784 is output from the third output terminal 711k and is input to the second input terminal 11b of the other control circuit (not shown). Therefore, when the first control signal S1 is delayed as described above, the delayed first control signal S1 is input to the other control circuit (not shown). Thus, in the other control circuit (not shown), the switching device 62 can also be driven on the basis of the dead time generated in the delay circuit 783.

When the two switching devices 61 and 62 are driven by the dead time generated as described above, both the first control signal S1 and the second control signal S2 input to the first input terminal 11a and the second input terminal 11b, respectively, are at the high level. Therefore, a signal output from the NAND circuit 782b is at the low level, and the signal input from the NAND circuit 782b to the NOR circuit 782e is inverted and is transitioned to the high level. Thus, the fault signal /FS1 output from the NOR circuit 782e to the fault output terminal 11c is at the low level, which indicates an abnormality. Therefore, when an abnormality occurs in which both the first control signal S1 and the second control signal S2 are at the high level, the fault signal /FS1 that indicates the occurrence of the abnormality is input to the controller 290.

In the above example, the example in which a dead time is generated when both the first control signal S1 and the second control signal S2 are at the high level, that is, when no dead time is provided has been described, but the present embodiment is not limited thereto. The input determination circuit 782 may operate to change the dead time to the generated dead time when the dead time becomes shorter than a set predetermined value.

### Eighth Embodiment

An eighth embodiment is different from the second embodiment in that two control circuits 810A and 810B are mounted in one semiconductor package. In the following description, the same components as those in the above-described embodiments may be denoted by the same reference numerals as appropriate, and descriptions thereof may be omitted.

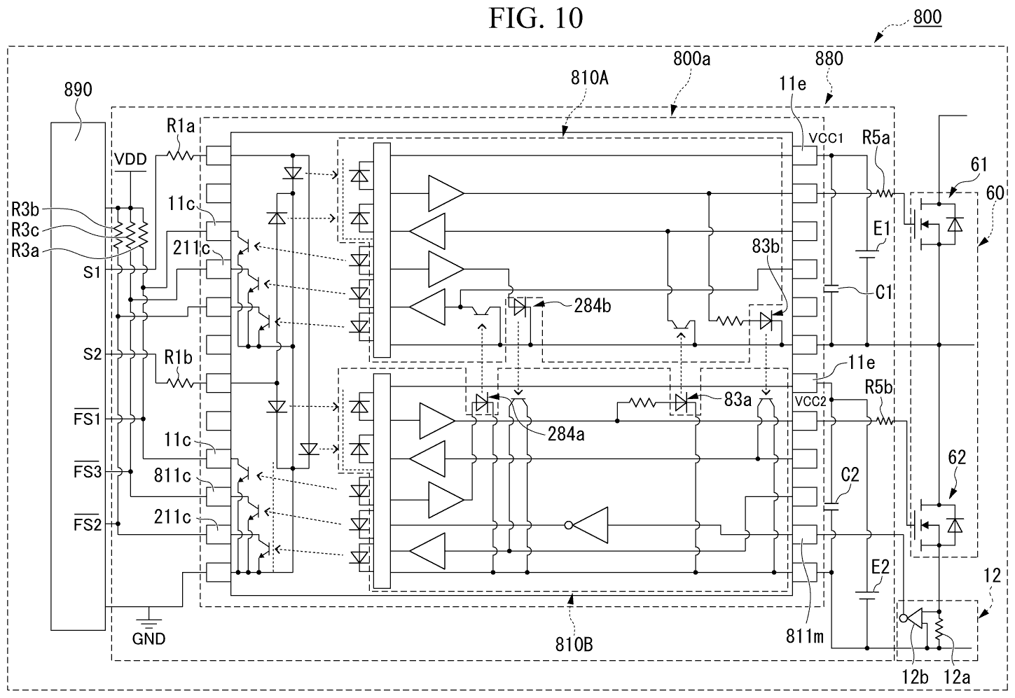

FIG. 10 is a circuit diagram showing a semiconductor circuit 800 according to the eighth embodiment. As shown in FIG. 10, a drive circuit 880 in a semiconductor circuit 800 includes a semiconductor package 800a, power supplies E1 and E2, resistor elements R1a, R1b, R3a, R3b, R3c, R5a, and R5b, and capacitors C1 and C2. The semiconductor package 800a includes a control circuit 810A and a control circuit 810B. The semiconductor package 800a also includes built-in insulation transmission devices having the same functions as the isolators 83a, 83b, 284a, and 284b in the second embodiment. In FIG. 10, insulation transmission devices having the same functions as the isolators 83a, 83b, 284a, and 284b are denoted by the same reference numerals as the isolators 83a, 83b, 284a, and 284b in the second embodiment, respectively. Each of the insulation transmission devices built into the semiconductor package 800a is not limited to an insulation transmission device using optical coupling such as the isolators 83a, 83b, 284a, and 284b in the second embodiment, but may be an insulation transmission device using magnetic coupling such as the insulation transmission device 450 in the fourth embodiment. Each of the insulation transmission devices built into the semiconductor package 800a may be an insulation transmission device using capacitive coupling such as the insulation transmission device 650 in the sixth embodiment. The semiconductor package 800a is configured by packaging, for example, the insulation transmission device, a semiconductor chip on which a control circuit 810A is mounted, and a semiconductor chip on which a control circuit 810B is mounted. The drive circuit 880 may include a semiconductor chip on which the insulation transmission device and the control circuits 810A and 810B are mounted, instead of the semiconductor package 800a.

In this embodiment, each of the control circuits 810A and 810B is a semiconductor chip having elements corresponding to the determination device 220, the conversion circuit 50a, and the photodiodes 51b and 52b in the second embodiment. Elements corresponding to elements other than the determination circuit 220, the conversion circuit 50a, and the photodiodes 51b and 52b in the control circuits 210A and 210B are provided in the semiconductor package 800a separately from the control circuits 810A and 810B, and function in the same manner as in the second embodiment. Each of the control circuits 810A and 810B may have elements corresponding to the elements of the control circuits 210A and 210B in the second embodiment other than the determination circuit 220, the conversion circuit 50a, and the photodiodes 51b and 52b.

The capacitor C1 and the resistor element R5a may be mounted on a semiconductor chip of the control circuit 810A built into the semiconductor package 800a. The capacitor C2 and the resistor element R5b may be mounted on a semiconductor chip of the control circuit 810B built into the semiconductor package 800a. When the devices that transmit the respective fault signals in an insulated manner among the elements built into the semiconductor package 800a are digital isolators, the resistor elements R1a, R1b, R3a, R3b, and R3c may be built into the semiconductor package 800a. In other words, all the elements constituting the drive circuit 880 other than the power supplies E1 and E2 may be provided in the semiconductor package 800a.

The semiconductor package 800a has a third fault output terminal 811c and a disable terminal 811m. The third fault output terminal 811c and the disable terminal 811m are connected to the control circuit 810B.

A third fault signal /FS3 based on the detection result of the overcurrent detection circuit 12 is output from the third fault output terminal 811c. The third fault signal /FS3 is input to the controller 890. The controller 890 is configured to input control signals for setting the states of the two switching devices 61 and 62 to the OFF state to the control circuits 810A and 810B, respectively, when the third fault signal /FS3 is at a low level. The resistor element R3c is disposed between the third fault output terminal 811c and a power supply terminal of terminals of the controller 890 to which the positive power supply voltage VDD is applied.

An output of the logic gate 12b of the overcurrent detection circuit 12 is input to the disable terminal 811m. When an overcurrent flows through the resistor element 12a of the overcurrent detection circuit 12 and the output from the logic gate 12b input to the disable terminal 811m is at the low level, the third fault signal /FS3 output from the third fault output terminal 811c is at the low level. Thus, the occurrence of an overcurrent in the bridge circuit 60 is transmitted to the controller 890, and the controller 890 inputs control signals to the control circuits 810A and 810B, respectively, to set the states of the two switching devices 61 and 62 to the OFF state. In the eighth embodiment, the fault signal /FS1 does not include a signal based on the detection result of the overcurrent detection circuit 12. The controller 890 is similar to the controller 290 of the second embodiment, except that the fault signal input thereto is different.

Other configurations of the control circuits 810A and 810B are similar to the other configurations of the control circuits 210A and 210B in the second embodiment, respectively. The other configuration of the drive circuit 880 is similar to the other configuration of the drive circuit 280 in the second embodiment. The other configurations of the semiconductor circuit 800 are similar to the other configurations of the semiconductor circuit 200 in the second embodiment.

### Ninth Embodiment

A ninth embodiment is different from the eighth embodiment in that various protection functions are added. In the following description, the same components as those in the above-described embodiments may be denoted by the same reference numerals as appropriate, and descriptions thereof may be omitted.

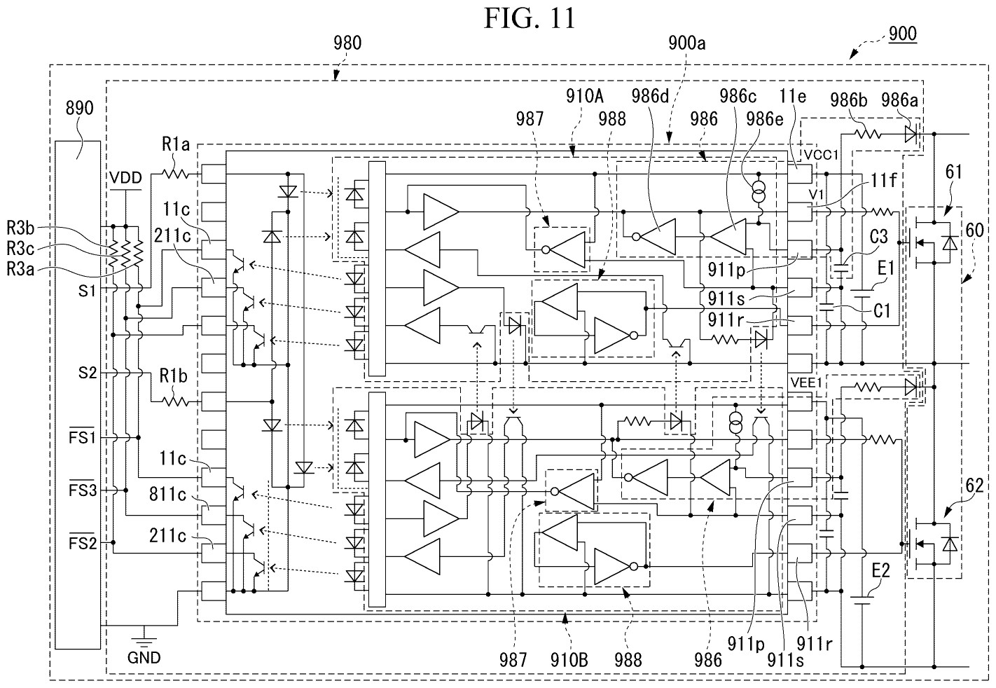

FIG. 11 is a circuit diagram showing a semiconductor circuit 900 according to the ninth embodiment. As shown in FIG. 11, a drive circuit 980 in the semiconductor circuit 900 includes a semiconductor package 900a having two control circuits 910A and 910B, as in the eighth embodiment. The semiconductor package 900a has a DESAT terminal 911p, an AMC terminal 911r, and a second negative power supply terminal 911s. Two DESAT terminals 911p, two AMC terminals 911r, and two second negative power supply terminals 911s are provided. One DESAT terminal 911p, one AMC terminal 911r, and one second negative power supply terminal 911s are connected to the control circuit 910A. The other DESAT terminal 911p, the other AMC terminal 911r, and the other second negative power supply terminal 911s are connected to the control circuit 910B. In the following description, the control circuit 910A will be described as an example of the control circuits 910A and 910B, and a description of the control circuit 910B may be omitted.

A negative power supply voltage VEE1 is applied to the second negative power supply terminal 911s connected to the control circuit 910A. A capacitor C3 is disposed between the DESAT terminal 911p and the second negative power supply terminal 911s. A gate terminal of the switching device 61 is connected to the AMC terminal 911r connected to the control circuit 910A.

A gate negative bias power supply for setting the gate terminal of each of the switching devices 61 and 62 to a negative potential may be provided on the semiconductor circuit 900 in order to prevent the switching devices 61 and 62 from being erroneously in the ON state when the switching devices 61 and 62 are in the OFF state. In this case, the second negative power supply terminal 911s may be disconnected from the negative power supply voltage VEE1 and may be connected to a negative terminal of the power supply E1 and a positive terminal of the gate negative bias power supply. In this case, the negative power supply voltage VEE1 may be applied to a negative terminal of the gate negative bias power supply.

The drive circuit 980 has two DESAT circuits 986, two UVLO circuits 987, and two AMC circuits 988. The two DESAT circuits 986, the two UVLO circuits 987, and the two AMC circuits 988 are connected to the two control circuits 910A and 910B, respectively. The DESAT circuit 986 connected to the control circuit 910B has the same configuration as the DESAT circuit 986 connected to the control circuit 910A, except that it is connected to the control circuit 910B. The UVLO circuit 987 connected to the control circuit 910B has the same configuration as the UVLO circuit 987 connected to the control circuit 910A, except that it is connected to the control circuit 910B. The AMC circuit 988 connected to the control circuit 910B has the same configuration as the AMC circuit 988 connected to the control circuit 910A, except that it is connected to the control circuit 910B. Therefore, in the following description, as representatives of the DESAT circuits 986, the UVLO circuits 987, and the AMC circuits 988 connected to the control circuits 910A and 910B, respectively, the DESAT circuit 986 connected to the control circuit 910A that is configured to control the switching device 61, the UVLO circuit 987 connected to the control circuit 910A, and the AMC circuit 988 connected to the control circuit 910A will be described.

The DESAT circuit 986 is a protection circuit which is configured to stop the output when the input voltage becomes higher than a predetermined value (Desaturation state). The DESAT circuit 986 includes a diode 986a, a resistor element 986b, a DESAT determination circuit 986c, a soft turn-off circuit 986d, a current source 986e, and a capacitor C3. An anode of the diode 986a is connected to the DESAT terminal 911p via the resistor element 986b. A cathode of the diode 986a is connected to a drain terminal of the switching device 61.

The DESAT determination circuit 986c, the soft turn-off circuit 986d, and the current source 986e are built into the semiconductor package 900a. An input from the DESAT terminal 911p and an input from the second negative power supply terminal 911s are input to the DESAT determination circuit 986c. The current source 986e is disposed between a wire connecting the DESAT determination circuit 986c and the DESAT terminal 911p and a wire to which the positive power supply voltage VCC1 is applied. The DESAT determination circuit 986c is configured to determine whether or not a drain voltage generated on the basis of a drain current flowing through the switching device 61 is higher than a predetermined value. The output of the DESAT determination circuit 986c is input to the soft turn-off circuit 986d. The soft turn-off circuit 986d is disposed between the DESAT determination circuit 986c and the output terminal 11f. The soft turn-off circuit 986d is configured to gently reduce the first output voltage V1 output from the output terminal 11f, and softly turn off the switching device 61 when the soft turn-off circuit 986d receives a determination result from the DESAT determination circuit 986c that the drain voltage generated in the switching device 61 is higher than a predetermined value. Thus, when the drain voltage generated in the switching device 61 becomes higher than a predetermined value, the state of the switching device 61 can be switched to the OFF state to protect the switching device 61.

The UVLO circuit 987 is a circuit having an under voltage lock out (UVLO) function. The UVLO circuit 987 is built into the semiconductor package 900a. The positive power supply voltage VCC1 and the voltage applied to the second negative power supply terminal 911s are input to the UVLO circuit 987. The UVLO circuit 987 is configured to set the state of the switching device 61 to the OFF state when the positive power supply voltage VCC1 becomes equal to or lower than a predetermined value. Thus, it is possible to curb the switching device 61 generating excessive heat.

The AMC circuit 988 is a circuit having an active miller clamp function. The AMC circuit 988 is built into the semiconductor package 900a. The AMC circuit 988 is connected to the AMC terminal 911r and a wire to which the negative power supply voltage VEE1 is applied. The AMC circuit 988 is configured to short the gate terminal of the switching device 61 to the wire to which the negative power supply voltage VEE1 is applied when the voltage at the gate terminal of the switching device 61 rises and the switching device 61 is about to self-turn on. The AMC circuit can curb the switching device 61 self-turning on by shorting the gate terminal of the switching device 61 to the wire to which the negative power supply voltage VEE1 is applied. Thus, it is possible to curb the bridge circuit 60 malfunctioning.

In this way, the protection function by the abnormality determination operation performed in the control circuit described in each of the above embodiments can be used in conjunction with other protection functions for the DESAT circuit 986, the UVLO circuit 987, the AMC circuit 988, and the like.

Other configurations of the control circuits 910A and 910B are similar to the other configurations of the control circuits 810A and 810B in the eighth embodiment, respectively. The other configurations of the drive circuit 980 are similar to the other configurations of the drive circuit 880 in the eighth embodiment. The other configurations of the semiconductor circuit 900 are similar to the other configurations of the semiconductor circuit 800 in the eighth embodiment.

### Tenth Embodiment

A tenth embodiment is an embodiment in which the semiconductor circuit 1000 is a circuit for driving a three-phase motor 1000m. In the following description, the same components as those in the above-described embodiments may be denoted by the same reference numerals as appropriate, and descriptions thereof may be omitted.

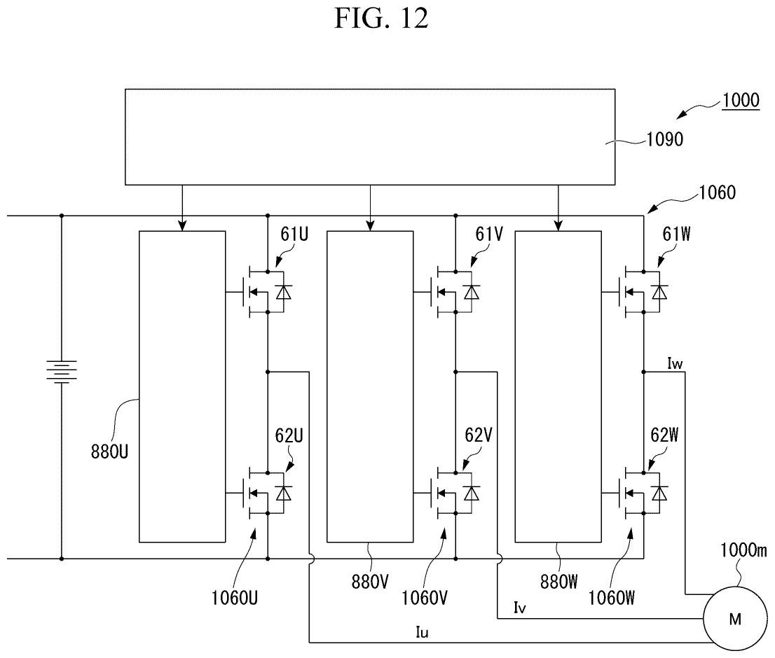

FIG. 12 is a circuit diagram showing a semiconductor circuit 1000 according to the tenth embodiment. As shown in FIG. 12, the semiconductor circuit 1000 includes a controller 1090, drive circuits 880U, 880V, and 880W, and a bridge circuit 1060. Each of the three drive circuits 880U, 880V, and 880W has the same configuration as the drive circuit 880 of the eighth embodiment. The three drive circuits 880U, 880V, and 880W are controlled by the controller 1090 in the same manner as in the above-described embodiments. The controller 1090 may have the same configuration as the controllers in each of the above-described embodiments.

The bridge circuit 1060 is a three-phase inverter circuit. The bridge circuit 1060 has three legs 1060U, 1060V, and 1060W connected in parallel with each other. The leg 1060U has two switching devices 61U and 62U connected to each other. The leg 1060V has two switching devices 61V and 62V connected to each other. The leg 1060W has two switching devices 61W and 62W connected to each other. The switching devices 61U, 61V, and 61W are similar to the switching device 61 in each of the above-described embodiments. The switching devices 62U, 62V, and 62W are similar to the switching device 62 in each of the above-described embodiments.

The leg 1060U is driven by the drive circuit 880U. The leg 1060V is driven by the drive circuit 880V. The leg 1060W is driven by the drive circuit 880W. The three-phase motor 1000m is supplied with a U-phase current Iu output from the leg 1060U, a V-phase current Iv output from the leg 1060V, and a W-phase current Iw output from the leg 1060W. The U-phase current Iu, the V-phase current Iv, and the W-phase current Iw are currents out of phase with each other. The three-phase motor 1000m is driven by being supplied with the U-phase current Iu, the V-phase current Iv, and the W-phase current Iw.

### Eleventh Embodiment

An eleventh embodiment is an embodiment including a non-insulated gate drive IC. In the following description, the same components as those in the above-described embodiments may be denoted by the same reference numerals as appropriate, and descriptions thereof may be omitted.

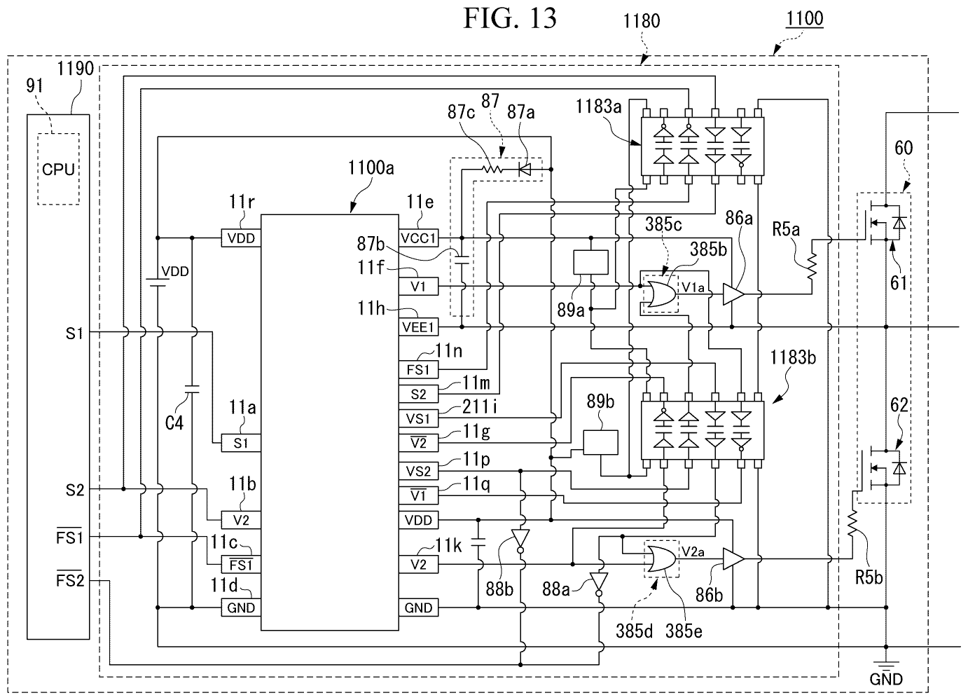

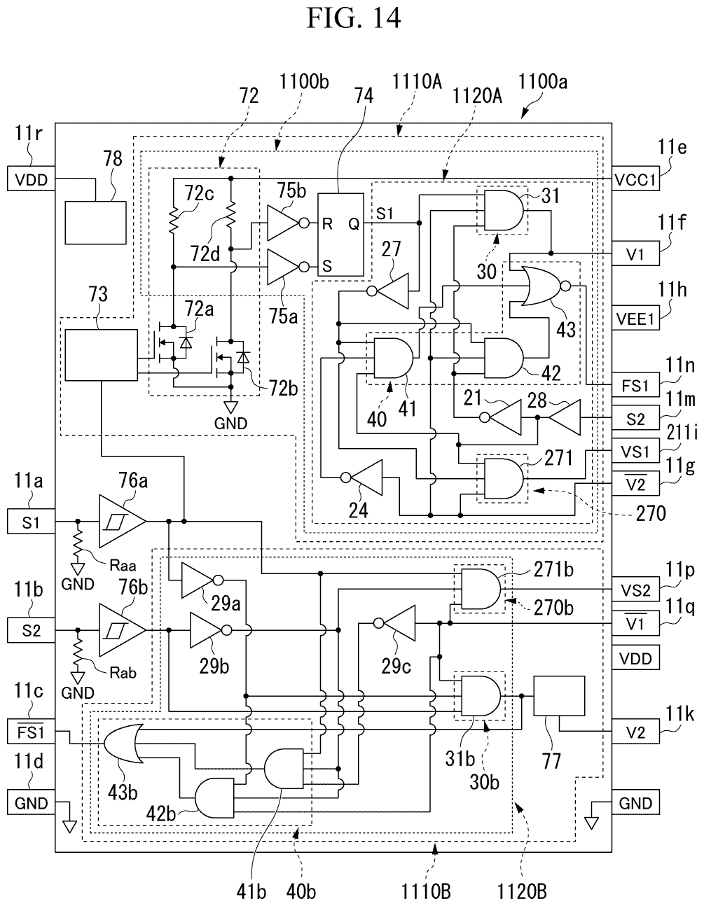

FIG. 13 is a circuit diagram showing a semiconductor circuit 1100 according to the eleventh embodiment. FIG. 14 is a circuit diagram showing a semiconductor package 1100a according to the eleventh embodiment. As shown in FIG. 13, a drive circuit 1180 in the semiconductor circuit 1100 includes a semiconductor package 1100a. As shown in FIG. 14, the semiconductor package 1100a has two control circuits 1110A and 1110B, as in the eighth embodiment. The semiconductor package 1100a is a non-insulated gate drive IC. The semiconductor package 1100a is a high voltage IC (HVIC).

The control circuit 1110A includes a determination circuit 1120A. The determination circuit 1120A includes an output determination circuit 30, a fault determination circuit 40, and an enable output determination circuit 270. The semiconductor package 1100a has two second input terminals 11b and 11m. As shown in FIG. 13, a second control signal S2 output from the controller 1190 is input to the second input terminal 11m via an isolator 1183a. The controller 1190 is similar to the controller 290 of the second embodiment, except that it has one CPU 91. The isolator 1183a is a digital isolator that transmits signals in an isolated manner by capacitive coupling. The positive power supply voltage VDD is input to the isolator 1183a via a regulator 89b as a power supply on the side to which the second control signal S2 is input. The regulator 89b is configured to step down the positive power supply voltage VDD. The positive power supply voltage VCC1 is input to the isolator 1183a via a regulator 89a as a power supply on the side to which the second control signal S2 is output. As shown in FIG. 14, the second control signal S2 input to the second input terminal 11m is inverted via the buffer circuit 28 and the NOT circuit 21 to become the second control signal /S2, and is then input to the AND circuit 31 of the output determination circuit 30 and the AND circuit 42 of the fault determination circuit 40. The second control signal S2 input to the second input terminal 11m is input to the AND circuit 41 of the fault determination circuit 40 and an AND circuit 271 of the enable output determination circuit 270 via the buffer circuit 28.

As shown in FIG. 13, a first output voltage V1 output from an AND circuit 31 of the output determination circuit 30 is input from the output terminal 11f to an OR circuit 385b of a buffer drive circuit 385c. The buffer drive circuit 385c is similar to the buffer drive circuit 385 in the third embodiment, except that it does not have the NOT circuit 385a. An enable signal VS2 output from the second output terminal 11p is input to the OR circuit 385b via an isolator 1183b. The isolator 1183b is a digital isolator that transmits signals in an isolated manner by capacitive coupling. The positive power supply voltage VDD is input to the isolator 1183b via a regulator 89b as a power supply on the side to which the enable signal VS2 is input. The positive power supply voltage VCC1 is input to the isolator 1183b via a regulator 89a as a power supply on the side to which the enable signal VS2 is output. The regulator 89a is configured to step down the positive power supply voltage VCC1. A first output voltage V1a output from the OR circuit 385b is input to the gate terminal of the switching device 61 via the buffer circuit 86a and the resistor element R5a. A positive power supply voltage VCC1 generated by a bootstrap circuit 87 is applied to the buffer circuit 86a. The positive power supply voltage VCC1 is a voltage based on the negative power supply voltage VEE1, which is the same potential as the potential of the source terminal of the switching device 61.

The bootstrap circuit 87 includes a bootstrap diode 87a, a bootstrap capacitor 87b, and a resistor element 87c. An anode of the bootstrap diode 87a is connected to a wire to which the positive power supply voltage VDD is applied. A cathode of the bootstrap diode 87a is connected to one end of the resistor element 87c. The other end of the resistor element 87c is connected to one electrode of the bootstrap capacitor 87b. The other electrode of the bootstrap capacitor 87b is connected to a wire that is connected to the negative power supply terminal 11h. In the bootstrap circuit 87, the bootstrap capacitor 87b is charged by the bridge circuit 60 performing a switching operation. The positive power supply voltage VCC1 is generated by charging the bootstrap capacitor 87b. Since the reference potential of the bootstrap capacitor 87b is the same as the potential of the source terminal of the switching device 61, when the switching device 61 is turned on, that is, when the switching device 62 is turned off, a positive power supply voltage VCC1 is generated in the bootstrap capacitor 87b as an even higher gate voltage for the source terminal of the switching device 61 at which a high potential of several hundreds of volts is generated, and the positive power supply voltage VCC1 is used as the gate drive power supply for driving the switching device 61.

The semiconductor package 1100a has two fault output terminals 11c and 11n. The fault output terminal 11n is a terminal that outputs a fault signal FS1. As shown in FIG. 14, the fault signal FS1 output from the NOR circuit 43 of the fault determination circuit 40 is output from the fault output terminal 11n. As shown in FIG. 13, the fault signal FS1 output from the fault output terminal 11n is inverted by the isolator 1183a to become a fault signal /FS1, and is input to the controller 1190.

As shown in FIG. 14, an enable signal VS1 output from the AND circuit 271 of the enable output determination circuit 270 is output from the second output terminal 211i. As shown in FIG. 13, the enable signal VS1 output from the second output terminal 211i is input to the buffer drive circuit 385d via the isolator 1183b. The buffer drive circuit 385d includes an OR circuit 385e. The enable signal VS1 and a second output voltage V2 output from the output terminal 11k are input to the OR circuit 385e. The OR circuit 385e is configured to output a second output voltage V2a to the gate terminal of the switching device 62 on the basis of the enable signal VS1 and the second output voltage V2. The OR circuit 385e is configured to output the second output voltage V2a which is at a high level when at least one of the enable signal VS1 and the second output voltage V2 is at the high level. The OR circuit 385e is configured to output the second output voltage V2a which is at a low level when both the enable signal VS1 and the second output voltage V2 are at the low level. The second output voltage V2a output from the OR circuit 385e is input to the gate terminal of the switching device 62 via the buffer circuit 86b and the resistor element R5b. The positive power supply voltage VDD is applied to the buffer circuit 86b. The enable signal VS1 output from the isolator 1183b is inverted by the NOT circuit 88a to become a second fault signal /FS2 and is input to the controller 1190.

As shown in FIG. 14, the control circuit 1110A includes a level shift circuit 72, a pulse generator 73, and a flip-flop 74. The level shift circuit 72 includes two switching devices 72a and 72b and two resistor elements 72c and 72d. The two switching devices 72a and 72b are transistors. More specifically, the two switching devices 72a and 72b are N-channel type field effect transistors. The two switching devices 72a and 72b are MOSFETs. Source terminals of the two switching devices 72a and 72b are connected to the ground GND. One end of the resistor element 72c is connected to a drain terminal of the switching device 72a. The other end of the resistor element 72c is connected to the positive power supply terminal 11e. The drain terminal of the switching device 72a is connected to a set terminal of the flip-flop 74 via a NOT circuit 75a. A voltage at the drain terminal of the switching device 72a is inverted by the NOT circuit 75a and is input to the flip-flop 74 as a set signal. One end of the resistor element 72d is connected to a drain terminal of the switching device 72b. The other end of the resistor element 72d is connected to the positive power supply terminal 11e. The drain terminal of the switching device 72b is connected to a reset terminal of the flip-flop 74 via a NOT circuit 75b. A voltage at the drain terminal of the switching device 72b is inverted by the NOT circuit 75b and is input to the flip-flop 74 as a reset signal.

The first control signal S1 input to the first input terminal 11a is input to the pulse generator 73 via a Schmitt trigger 76a. The pulse generator 73 is configured to output a pulse voltage to the gate terminal of the switching device 72a when the input first control signal S1 is transitioned from the low level to the high level. The pulse generator 73 is configured to output a pulse voltage to the gate terminal of the switching device 72b when the input first control signal S1 is transitioned from the high level to the low level.

When the pulse voltage is input from the pulse generator 73 to the gate terminal of the switching device 72a, the switching device 72a is in the ON state, and the voltage at the drain terminal of the switching device 72a is at the low level. Therefore, the set signal input to flip-flop 74 is at the high level. When a pulse voltage is input from the pulse generator 73 to the gate terminal of the switching device 72b, the switching device 72b is in the ON state, and the voltage at the drain terminal of the switching device 72b is at the low level. Therefore, the reset signal input to the flip-flop 74 is at the high level.

The voltage at the drain terminal of the switching device 72a when the switching device 72a is in the ON state is determined according to a magnitude of a resistance value of the resistor element 72c and a magnitude of on-resistance of the switching device 72a. The voltage at the drain terminal of the switching device 72b when the switching device 72b is in the ON state is determined according to a magnitude of a resistance value of the resistor element 72d and a magnitude of on-resistance of the switching device 72b. Therefore, the voltages of the set signal and the reset signal output from the level shift circuit 72 can be set based on the magnitude of the resistance values of the resistor elements 72c and 72d and the magnitude of the on-resistances of the switching devices 72a and 72b. Thus, the level shift circuit 72 can convert a voltage level of the first control signal S1 input to the first input terminal 11a. In the eleventh embodiment, the level shift circuit 72 increases (shifts up), that is, boosts the voltage level of the first control signal S1.

The flip-flop 74 is configured to output an output signal which is at the high level when the set signal is at the high level and the reset signal is at the low level. The flip-flop 74 is configured to output the output signal which is at the low level when the set signal is at the low level and the reset signal is at the high level. The flip-flop 74 is configured to maintain a level of the output signal in the previous level when both the set signal and the reset signal are at the low level. The signal output from the flip-flop 74 is the first control signal S1 of which a voltage level has been converted by the level shift circuit 72. The first control signal S1 output from the flip-flop 74 is input to the AND circuit 31 of the output determination circuit 30. The first control signal S1 output from the flip-flop 74 is inverted by the NOT circuit 27 to become the first control signal /S1, and is input to the AND circuits 41 and 42 of the fault determination circuit 40 and the AND circuit 271 of the enable output determination circuit 270.

In the semiconductor package 1100a of the eleventh embodiment, a region including the determination circuit 1120A, the flip-flop 74, the NOT circuits 75a and 75b, and the resistor elements 72c and 72d is a high-voltage well 1100b.

The control circuit 1110B includes a determination circuit 1120B and a delay circuit 77. The determination circuit 1120B includes an output determination circuit 30b, a fault determination circuit 40b, and an enable output determination circuit 270b. The output determination circuit 30b includes an AND circuit 31b. Three signals including the second control signal S2, the first control signal /S1, and the first output voltage /V1 are input to the AND circuit 31b. In the control circuit 1110o, the output determination circuit 30b functions similarly to the output determination circuit 30 in the control circuit 1110A. The second output voltage V2 is output from the AND circuit 31b of the output determination circuit 30b. The second output voltage V2 output from the AND circuit 31b is delayed by the delay circuit 77 and then is output from the output terminal 11k. As shown in FIG. 13, the second output voltage V2 output from the output terminal 11k is input to the OR circuit 385e of the buffer drive circuit 385d. The second output voltage V2 output from the output terminal ilk is inverted by the isolator 1183b to become the second output voltage /V2, and is input to the third input terminal 11g.

In the control circuit 1110B, the fault determination circuit 40b functions similarly to the fault determination circuit 40 in the control circuit 1110A. As shown in FIG. 14, the fault determination circuit 40b includes an AND circuit 41b, an AND circuit 42b, and an OR circuit 43b. Three signals including the first control signal S1, the second control signal /S2, and the first output voltage V1 are input to the AND circuit 41b. The first control signal S1 input to the first input terminal 11a is input to the AND circuit 41b via the Schmitt trigger 76a. The second control signal /S2 input from the second input terminal 11b via the Schmitt trigger 76b to the NOT circuit 29b and then inverted is input to the AND circuit 41b. The first output voltage /V1 input to the third input terminal 11q is inverted by the NOT circuit 29c to become the first output voltage V1, and is then input to the AND circuit 41b. The first output voltage /V1 obtained by inverting the first output voltage V1 output from the output terminal 11f by the isolator 1183b is input to the third input terminal 11q. The AND circuit 41b is configured to output an output signal which is at the high level when all the three input signals are at the high level. The AND circuit 41b is configured to output the output signal which is at the low level when at least one of the three input signals is at the low level.

Three signals including the first control signal /S1, the second control signal /S2, and the first output voltage /V1 are input to the AND circuit 42b. The first control signal /S1 input from the first input terminal 11a via the Schmitt trigger 76a to the NOT circuit 29a and then inverted is input to the AND circuit 42b. The second control signal /S2 input from the second input terminal 11b via the Schmitt trigger 76b to the NOT circuit 29b and then inverted is input to the AND circuit 42b. The first output voltage /V1 input to the third input terminal 11q is input to the AND circuit 42b. The AND circuit 42b is configured to output an output signal which is at the high level when all the three input signals are at the high level. The AND circuit 42b is configured to output the output signal which is at the low level when at least one of the three input signals is at the low level.

Three signals including a signal output from the AND circuit 41b, a signal output from the AND circuit 42b, and a signal output from the AND circuit 31b are input to the OR circuit 43b. The OR circuit 43b is configured to output a fault signal /FS1. The OR circuit 43b is configured to output the fault signal /FS1 which is at the high level when at least one of the three input signals is at the high level. The OR circuit 43b is configured to output the fault signal /FS1 which is at the low level when all the three input signals are at the low level. The fault signal /FS1 output from the OR circuit 43b is input from the fault output terminal 11c to the controller 1190.

In the control circuit 1110B, the enable output determination circuit 270b functions similarly to the enable output determination circuit 270 in the control circuit 1110A. The enable output determination circuit 270b includes an AND circuit 271b. Three signals including the first control signal S1, the second control signal /S2, and the first output voltage /V1 are input to the AND circuit 271b. The first control signal S1 is input from the first input terminal 11a to the AND circuit 271b via the Schmitt trigger 76a. The second control signal /S2 input from the second input terminal 11b via the Schmitt trigger 76b to the NOT circuit 29b and then inverted is input to the AND circuit 271b. The first output voltage /V1 input to the third input terminal 11q is input to the AND circuit 271b. The AND circuit 271b is configured to output an enable signal VS2 to the second output terminal 11p. The AND circuit 271b is configured to output the enable signal VS2 which is at the high level when all the three input signals are at the high level. The AND circuit 271b is configured to output the enable signal VS2 which is at the low level when at least one of the three input signals is at the low level.

One end of a resistor element Raa is connected to a wire that connects the first input terminal 11a and the Schmitt trigger 76a. The other end of the resistor element Raa is connected to the ground GND. One end of a resistor element Rab is connected to a wire that connects the second input terminal 11b and the Schmitt trigger 76b. The other end of the resistor element Rab is connected to the ground GND. The positive power supply voltage VDD is input from a power supply terminal 11r to the semiconductor package 1100a. The positive power supply voltage VDD input to the power supply terminal 11r is used within the semiconductor package 1100a via an internal voltage regulator 78. The internal voltage regulator 78 is configured to step down the positive power supply voltage VDD. As shown in FIG. 13, a capacitor C4 is disposed between a wire connected to the power supply terminal 11r from the outside of the semiconductor package 1100a and a wire connected to the ground terminal 11d from the outside of the semiconductor package 1100a.

In the eleventh embodiment, the isolators 1183a and 1183b are not particularly limited as long as they can transmit signals in an insulated manner, and may be isolators other than digital isolators, such as photocouplers. In addition, the isolators 1183a and 1183b may be digital isolators that transmit signals in an isolated manner by magnetic coupling. Furthermore, the isolators 1183a and 1183b may not be provided. In this case, the voltage level may be adjusted by providing a level shift circuit in addition to the level shift circuit 72 inside the semiconductor package 1100a.

### Twelfth Embodiment

A twelfth embodiment is an embodiment in which a bridge circuit 1260 is a multilevel inverter circuit. In the following description, the same components as those in the above-described embodiments may be denoted by the same reference numerals as appropriate, and descriptions thereof may be omitted.

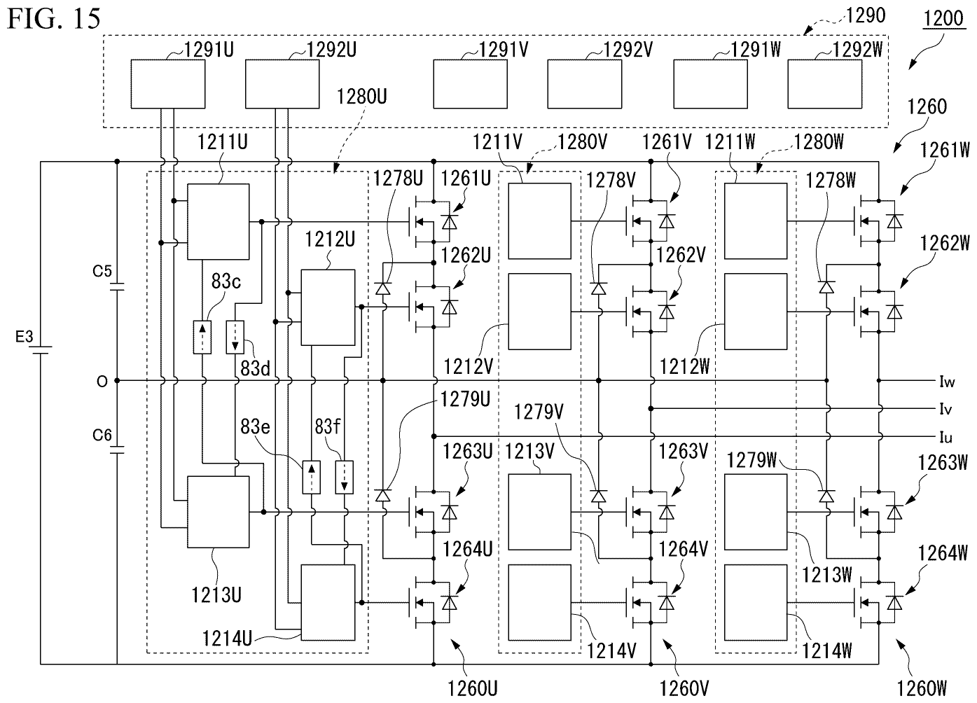

FIG. 15 is a circuit diagram showing a semiconductor circuit 1200 according to the twelfth embodiment. As shown in FIG. 15, the semiconductor circuit 1200 includes a controller 1290, drive circuits 1280U, 1280V, and 1280W, and a bridge circuit 1260. The controller 1290 has control ICs 1291U, 1291V, 1291W, 1292U, 1292V, and 1292W. The control IC 1291U and the control IC 1292U are configured to control a drive circuit 1280U. The control IC 1291V and the control IC 1292V are configured to control a drive circuit 1280V The control IC 1291W and the control IC 1292W are configured to control a drive circuit 1280W.

The drive circuit 1280U, the drive circuit 1280V, and the drive circuit 1280W have the same configuration except that phases of legs of the bridge circuit 1260 are different from each other. For this reason, in FIG. 15, a connection relationship between control circuits 1211V to 1214V in the drive circuit 1280V which will be described below, a connection relationship between control circuits 1211W to 1214W in the drive circuit 1280W which will be described below, a connection relationship between the drive circuit 1280V and the control ICs 1291V and 1292V, and a connection relationship between the drive circuit 1280W and the control ICs 1291W and 1292W are omitted from illustration.

The bridge circuit 1260 is a three-phase multilevel inverter circuit. The bridge circuit 1260 has three legs 1260U, 1260V, and 1260W connected in parallel to each other. The leg 1260U has four switching devices 1261U, 1262U, 1263U, and 1264U connected in series. The leg 1260V has four switching devices 1261V, 1262V, 1263V, and 1264V connected in series. The leg 1260W has four switching devices 1261W, 1262W, 1263W, and 1264W connected in series. Each of the switching devices of the bridge circuit 1260 is a transistor. More specifically, each of the switching devices of the bridge circuit 1260 is an N-channel type field effect transistor. Each of the switching devices of the bridge circuit 1260 is a MOSFET.

A drain terminal of the switching device 1261U is connected to a positive electrode of a power supply E3. A source terminal of the switching device 1261U is connected to a drain terminal of the switching device 1262U. A source terminal of the switching device 1262U is connected to a drain terminal of the switching device 1263U. A source terminal of the switching device 1263U is connected to a drain terminal of the switching device 1264U. A source terminal of the switching device 1264U is connected to a negative electrode of the power supply E3. A U-phase current Iu is output from a wire that connects the switching device 1262U and the switching device 1263U.

The switching devices 1261V to 1264V are connected in the same manner as the switching devices 1261U to 1264U. A V-phase current Iv is output from a wire that connects the switching device 1262V and the switching device 1263V The switching devices 1261W to 1264W are connected in the same manner as the switching devices 1261U to 1264U. A W-phase current Iw is output from a wire that connects the switching device 1262W and the switching device 1263W.

The bridge circuit 1260 includes two capacitors C5 and C6 connected in series. One electrode of the capacitor C5 is connected to the positive electrode of the power supply E3. The other electrode of the capacitor C5 is connected to one electrode of the capacitor C6. The other electrode of the capacitor C6 is connected to the negative electrode of the power supply E3.

The bridge circuit 1260 includes clamp diodes 1278U, 1278V, 1278W, 1279U, 1279V, and 1279W. An anode of the clamp diode 1278U is connected to a neutral point O between the capacitor C5 and the capacitor C6. A cathode of the clamp diode 1278U is connected to a wire that connects the switching device 1261U and the switching device 1262U. An anode of the clamp diode 1279U is connected to a wire that connects the switching device 1263U and the switching device 1264U. A cathode of the clamp diode 1279U is connected to the neutral point O between the capacitor C5 and the capacitor C6.

An anode of the clamp diode 1278V is connected to the neutral point O between the capacitor C5 and the capacitor C6. A cathode of the clamp diode 1278V is connected to a wire that connects the switching device 1261V and the switching device 1262V. An anode of the clamp diode 1279V is connected to a wire that connects the switching device 1263V and the switching device 1264V A cathode of the clamp diode 1279V is connected to the neutral point O between the capacitor C5 and the capacitor C6.

An anode of the clamp diode 1278W is connected to the neutral point O between the capacitor C5 and the capacitor C6. A cathode of the clamp diode 1278W is connected to a wire that connects the switching device 1261W and the switching device 1262W. An anode of the clamp diode 1279W is connected to a wire that connects the switching device 1263W and the switching device 1264W. A cathode of the clamp diode 1279W is connected to the neutral point O between the capacitor C5 and the capacitor C6.

The drive circuit 1280U has control circuits 1211U, 1212U, 1213U, and 1214U. Each of the control circuits 1211U to 1214U is an integrated circuit having the same configuration as the control circuit 10 in the first embodiment. The control circuit 1211U is configured to control the switching device 1261U. The control circuit 1212U is configured to control the switching device 1262U. The control circuit 1213U is configured to control the switching device 1263U. The control circuit 1214U is configured to control the switching device 1264U.

In the twelfth embodiment, the state of the switching device 1261U and the state of the switching device 1263U are alternately switched to the ON state. The state of the switching device 1262U and the state of the switching device 1264U are alternately switched to the ON state. In the bridge circuit 1260 which is a multilevel inverter circuit, a switching operation of the leg 1260U is a switching operation in which the state is switched sequentially between a first state, a second state, and a third state. The first state is a state in which the switching device 1261U and the switching device 1262U are in the ON state, and the switching device 1263U and the switching device 1264U are in the OFF state. The second state is a state in which the switching device 1262U and the switching device 1263U are in the ON state, and the switching device 1261U and the switching device 1264U are in the OFF state. The third state is a state in which the switching device 1263U and the switching device 1264U are in the ON state, and the switching device 1261U and the switching device 1262U are in the OFF state. On the basis of a command from the controller 1290, the control circuits 1211U to 1214U respectively control the switching devices 1261U to 1264U so that the state of the leg 1260U is switched sequentially between the first state, the second state, and the third state. The switching operation of the leg 1260V and the switching operation of the leg 1260W are similar to the switching operation of the leg 1260U, except that the timings are different from each other.

A control signal for controlling the switching device 1261U and a control signal for controlling the switching device 1263U are input from the control IC 1291U of the controller 1290 to the control circuit 1211U. An output voltage output from the control circuit 1213U to the gate terminal of the switching device 1263U is input in an inverted state via an isolator 83c to the control circuit 1211U. The isolator 83c is, for example, an optical coupler having a light emitting diode and a phototransistor. The isolator 83c may have any configuration as long as it can transmit signals in an isolated manner. In the control circuit 1211U, the switching device 1261U is a “first switching device” controlled by the control circuit 1211U itself, and the switching device 1263U is a “second switching device” controlled by another control circuit 1213U.

A control signal for controlling the switching device 1263U and a control signal for controlling the switching device 1261U are input from the control IC 1291U of the controller 1290 to the control circuit 1213U. An output voltage output from the control circuit 1211U to the gate terminal of the switching device 1261U is input in an inverted state via an isolator 83d to the control circuit 1213U. The isolator 83d is, for example, an optical coupler having a light emitting diode and a phototransistor. The isolator 83d may have any configuration as long as it can transmit signals in an insulated manner. In the control circuit 1213U, the switching device 1263U is a “first switching device” controlled by the control circuit 1213U itself, and the switching device 1261U is a “second switching device” controlled by another control circuit 1211U.

The control circuits 1211U and 1213U are configured to monitor each other's control signals and output voltages in the same way that the control circuits 10A and 10B in the first embodiment monitor each other's control signals and output voltages. An operation of the control circuit 1211U is similar to that of the control circuit 10A in the first embodiment. An operation of the control circuit 1213U is similar to that of the control circuit 10B in the first embodiment.

A control signal for controlling the switching device 1262U and a control signal for controlling the switching device 1264U are input from the control IC 1292U of the controller 1290 to the control circuit 1212U. An output voltage output from the control circuit 1214U to the gate terminal of the switching device 1264U is input in an inverted state via an isolator 83e to the control circuit 1212U. The isolator 83e is, for example, an optical coupler having a light emitting diode and a phototransistor. The isolator 83e may have any configuration as long as it can transmit signals in an isolated manner. In the control circuit 1212U, the switching device 1262U is a “first switching device” controlled by the control circuit 1212U itself, and the switching device 1264U is a “second switching device” controlled by another control circuit 1214U.

A control signal for controlling the switching device 1264U and a control signal for controlling the switching device 1262U are input from the control IC 1292U of the controller 1290 to the control circuit 1214U. An output voltage output from the control circuit 1212U to the gate terminal of the switching device 1262U is input in an inverted state via an isolator 83f to the control circuit 1214U. The isolator 83f is, for example, an optical coupler having a light emitting diode and a phototransistor. The isolator 83f may have any configuration as long as it can transmit signals in an isolated manner. In the control circuit 1214U, the switching device 1264U is a “first switching device” controlled by the control circuit 1214U itself, and the switching device 1262U is a “second switching device” controlled by another control circuit 1212U.

The control circuits 1212U and 1214U are configured to monitor each other's control signals and output voltages in the same way that the control circuits 10A and 10B in the first embodiment monitor each other's control signals and output voltages. An operation of the control circuit 1212U is similar to that of the control circuit 10A in the first embodiment. An operation of the control circuit 1214U is similar to that of the control circuit 10B in the first embodiment.

The drive circuit 1280V has control circuits 1211V, 1212V, 1213V, and 1214V Each of the control circuits 1211V to 1214V is an integrated circuit having the same configuration as the control circuit 10 in the first embodiment. The control circuit 1211V is configured to control the switching device 1261V. The control circuit 1212V is configured to control the switching device 1262V The control circuit 1213V is configured to control the switching device 1263V The control circuit 1214V is configured to control the switching device 1264V The drive circuit 1280V operates similarly to the drive circuit 1280U, except that it drives the V-phase leg 1260V. The control circuits 1211V and 1213V are configured to monitor each other's control signals and output voltages in the same way that the control circuits 10A and 10B in the first embodiment monitor each other's control signals and output voltages. The control circuits 1212V and 1214V are configured to monitor each other's control signals and output voltages in the same way that the control circuits 10A and 10B in the first embodiment monitor each other's control signals and output voltages.

The drive circuit 1280W has control circuits 1211W, 1212W, 1213W, and 1214W. Each of the control circuits 1211W to 1214W is an integrated circuit having a configuration similar to that of the control circuit 10 in the first embodiment. The control circuit 1211W is configured to control the switching device 1261W. The control circuit 1212W is configured to control the switching device 1262W. The control circuit 1213W is configured to control the switching device 1263W. The control circuit 1214W is configured to control the switching device 1264W. The drive circuit 1280W operates in the same manner as the drive circuit 1280U, except that it drives the W-phase leg 1260W. The control circuits 1211W and 1213W are configured to monitor each other's control signals and output voltages in the same way that the control circuits 10A and 10B in the first embodiment monitor each other's control signals and output voltages. The control circuits 1212W and 1214W are configured to monitor each other's control signals and output voltages in the same way that the control circuits 10A and 10B in the first embodiment monitor each other's control signals and output voltages.

According to at least one of the embodiments described above, the control circuit is a control circuit provided in a drive circuit that is configured to drive a bridge circuit having a plurality of switching devices by controlling the plurality of switching devices respectively using a plurality of control circuits. The control circuit is configured such that a first control signal for controlling a first switching device that is controlled by the control circuit itself among the plurality of switching devices, and a second control signal for controlling a second switching device that is controlled by the other control circuit among the plurality of switching devices are input to the control circuit. Thus, the control circuit can compare the first control signal for controlling the first switching device controlled by the control circuit itself with the second control signal for controlling the second switching device controlled by the other control circuit, and can grasp whether or not an abnormality has occurred in the control signals. Therefore, it is possible to curb the plurality of switching devices being short-circuited to each other, and to curb an overcurrent flowing through the bridge circuit. Thus, it is possible to curb the switching devices being damaged.

The control circuit of the embodiments may have any configuration and may operate in any manner as long as the first control signal for controlling the first switching device controlled by the control circuit itself and the second control signal for controlling the second switching device controlled by another control circuit are input. The number of switching devices included in the bridge circuit is not particularly limited as long as it is two or more. The bridge circuit may be a full bridge circuit. When the bridge circuit has three or more switching devices, a plurality of second control signals for respectively controlling a plurality of second switching devices controlled by a plurality of other control circuits may be input to the control circuit of the embodiments. In addition, the second control signal input to the control circuit of the embodiments may be a control signal for controlling any of the plurality of switching devices included in the bridge circuit, as long as it is a control signal for controlling a switching device other than the switching device that is controlled by the control circuit itself. For example, when a bridge circuit has a U-phase leg, a V-phase leg, and a W-phase leg, like bridge circuit 1060 in the tenth embodiment, some or all of five second control signals for controlling five switching devices other than the switching device that is controlled by the control circuit itself may be input to the control circuit of the embodiments. For example, a first control signal for controlling a switching device included in a leg of a phase that is controlled by the control circuit itself, and a second control signal for controlling a switching device included in one or more legs of other phases may be input to a control circuit for controlling a switching device included in a leg of a certain phase among the U phase, the V phase, and the W phase. For example, a first control signal for controlling one switching device (the first switching device) of the U-phase high-side switching device and the W-phase low-side switching device that is controlled by the control circuit itself, and a second control signal for controlling the other switching device (the second switching device) of the U-phase high-side switching device and the W-phase low-side switching device may be input to each of the control circuits that control the high-side switching device of the U-phase leg and the low-side switching device of the W-phase leg. In addition, for example, a first control signal for controlling a switching device (the first switching device) controlled by the control circuit itself, and two second control signals for controlling two other switching devices (the second switching devices) controlled by the other two control circuits may be input to each of the control circuits that control the high-side switching device of the U-phase leg, the low-side switching device of the V-phase leg, and the low-side switching device of the W-phase leg. The number of second control signals input to each of the control circuits is not particularly limited as long as it is equal to or greater than 1. The control circuits, drive circuits, and semiconductor circuits of the embodiments may be used for any purpose.

Each of the functions including the abnormality determination operation in the control circuit of each of the above-described embodiments may be realized by any method as long as the functions can be realized. At least some of the functions of the control circuit may be realized by, for example, a processor such as a CPU executing a program stored in a storage medium (not shown), that is, software, or may be realized by hardware including circuits such as a large scale integration (LSI), an application specific integrated circuit (ASIC), a field-programmable gate array (FPGA), and a graphics processing unit (GPU), and may be realized by cooperation between software and hardware. The storage medium (not shown) is realized by a storage medium such as a random-access memory (RAM), a read only memory (ROM), a hard disk drive (HDD), or a flash memory.

In the above-described embodiments, the insulation transmission device and the isolator are provided so that signal transmission from the controller to each of the control circuits and signal transmission between two control circuits are insulated transmission, but the embodiments is not limited thereto. Each of the signals may be transmitted directly without being transmitted in an isolated manner. Furthermore, the methods for transmitting signals in an isolated manner which are described in each of the embodiments may be appropriately combined in each of the embodiments, or may be appropriately replaced with the insulation transmission methods in other embodiments. In modified cases of the above-described embodiments, the high levels of each of the signals may be different from each other. In modified cases of the above-described embodiments, the low levels of each of the signals may be different from each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A control circuit provided in a drive circuit that is configured to drive a bridge circuit having a plurality of switching devices by controlling the plurality of switching devices respectively using a plurality of control circuits,
wherein the control circuit is configured such that a first control signal for controlling a first switching device that is controlled by the control circuit itself among the plurality of switching devices, and a second control signal for controlling a second switching device that is controlled by another control circuit among the plurality of switching devices are input to the control circuit.

2. The control circuit according to claim 1, wherein the control circuit is configured to perform an abnormality determination operation for determining whether or not an abnormality has occurred in at least one of a control state of the first switching device and a control state of the second switching device, and
the abnormality determination operation includes determining whether or not an abnormality occurs in at least one of the control state of the first switching device and the control state of the second switching device on the basis of the first control signal and the second control signal.

3. The control circuit according to claim 2, wherein the control circuit is configured such that device information indicating a state of the second switching device is input to the control circuit, and
the abnormality determination operation includes determining whether or not an abnormality occurs in at least one of the control state of the first switching device and the control state of the second switching device on the basis of the first control signal, the second control signal, and the device information.

4. The control circuit according to claim 3, wherein the device information includes information based on a drive voltage applied to the second switching device.

5. The control circuit according to claim 4, wherein the abnormality determination operation includes determining whether or not the state of the second switching device is in a normal state on the basis of the first control signal, the second control signal, and the device information, and
the control circuit is configured such that when it is determined in the abnormality determination operation that the state of the second switching device is not in the normal state, the control circuit outputs a signal for setting the state of the second switching device to be in the normal state.

6. The control circuit according to claim 5, wherein the control circuit is configured to output the signal for setting the second switching device to be in the normal state to a control circuit that controls the second switching device.

7. The control circuit according to claim 2, wherein the abnormality determination operation includes determining whether or not the first switching device and the second switching device will be in an ON state concurrently, and
the control circuit is configured to set the first switching device to an OFF state when it is determined in the abnormality determination operation that the first switching device and the second switching device will be in the ON state concurrently.

8. The control circuit according to claim 2, wherein the abnormality determination operation includes determining whether or not an abnormality occurs in a dead time in which both the first switching device and the second switching device are in an OFF state, and
the control circuit is configured such that when it is determined in the abnormality determination operation that an abnormality occurs in the dead time, the control circuit generates a predetermined dead time and controls the first switching device on the basis of the generated dead time.

9. The control circuit according to claim 2, wherein the control circuit is configured to output a signal which indicates that an abnormality has occurred when it is determined in the abnormality determination operation that an abnormality occurs in at least one of the control state of the first switching device and the control state of the second switching device.

10. A drive circuit which is configured to drive a bridge circuit having a plurality of switching devices, comprising:
a plurality of control circuits,
wherein the plurality of control circuits respectively are configured to control the plurality of switching devices, and
the drive circuit is configured such that a first control signal for controlling a first switching device that is controlled by the control circuit itself among the plurality of switching devices, and a second control signal for controlling a second switching device that is controlled by another control circuit among the plurality of switching devices are input to each of the plurality of control circuits.

11. The control circuit according to claim 10, wherein at least one of the plurality of control circuits is configured to control the switching device controlled by the other control circuit instead of the other control circuit when the other control circuit among the plurality of control circuits stops.

12. A semiconductor circuit comprising:
a bridge circuit having a plurality of switching devices; and
a drive circuit configured to drive the bridge circuit,
wherein the drive circuit includes a plurality of control circuits,
the plurality of control circuits respectively are configured to control the plurality of switching devices, and
the semiconductor circuit is configured such that a first control signal for controlling a first switching device that is controlled by the control circuit itself among the plurality of switching devices, and a second control signal for controlling a second switching device that is controlled by another control circuit among the plurality of switching devices are input to each of the plurality of control circuits.
